(19) United States
(12) Patent Application Publication
(10) Pub. No.: US 2025/0029935 A1
(43) Pub. Date: Jan. 23, 2025

(54) SEMICONDUCTOR PACKAGE

(71) Applicant: SAMSUNG ELECTRONICS CO., LTD., Suwon-si (KR)

(72) Inventors: Kyuil Hwang, Suwon-si (KR); Minkyu Kim, Suwon-si (KR); Joongsun Kim, Suwon-si (KR); Pyunghwa Han, Suwon-si (KR)

(21) Appl. No.: 18/605,312

(22) Filed: Mar. 14, 2024

(30) Foreign Application Priority Data
Jul. 18, 2023 (KR) 10-2023-0093389

(51) Int. Cl. H01L 23/552; H01L 21/48; H01L 23/00; H01L 23/498; H01L 25/10; H01L 25/18

(52) U.S. Cl. CPC H01L 23/552; H01L 21/4857; H01L 21/486; H01L 23/49822; H01L 23/49833; H01L 23/49838; H01L 25/105; H01L 25/18; H01L 24/05; H01L 24/08; H01L 24/13; H01L 24/16; H01L 2224/05147; H01L 2224/08225; H01L 2224/13147; H01L 2224/16237; H01L 2225/1023; H01L 2225/1041; H01L 2225/1058; H01L 2924/181

(57) ABSTRACT

Disclosed are semiconductor packages and their fabrication methods. The semiconductor package comprises a lower redistribution substrate, an upper redistribution substrate, and a semiconductor chip between the lower redistribution substrate and the upper redistribution substrate. The lower redistribution substrate includes a lower dielectric structure, a lower redistribution pattern surrounded by the lower dielectric structure, and a lower shield structure surrounded by the lower dielectric structure and surrounding the lower redistribution pattern. The upper redistribution substrate includes an upper dielectric structure, an upper redistribution pattern surrounded by the upper dielectric structure, and an upper shield structure surrounded by the upper dielectric structure and surrounding the upper redistribution pattern.

### CROSS-REFERENCE TO RELATED APPLICATION

This U.S. nonprovisional application claims priority under 35 U.S.C. § 119 to Korean Patent Application No. 10-2023-0093389, filed on Jul. 18, 2023, in the Korean Intellectual Property Office, the disclosure of which is hereby incorporated by reference in its entirety.

### BACKGROUND

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability and durability of semiconductor packages.

### SUMMARY

The subject matter of the present disclosure generally relates to a semiconductor package with improved electrical properties and increased reliability.

In an aspect, a semiconductor package includes: a lower redistribution substrate; an upper redistribution substrate; and a semiconductor chip between the lower redistribution substrate and the upper redistribution substrate. The lower redistribution substrate may include: a lower dielectric structure; a lower redistribution pattern surrounded by the lower dielectric structure; and a lower shield structure surrounded by the lower dielectric structure and surrounding the lower redistribution pattern. The upper redistribution substrate may include: an upper dielectric structure; an upper redistribution pattern surrounded by the upper dielectric structure; and an upper shield structure surrounded by the upper dielectric structure and surrounding the upper redistribution pattern.

In an aspect, a semiconductor package includes: a lower redistribution substrate; and a semiconductor chip mounted on the lower redistribution substrate. The lower redistribution substrate may include: a lower dielectric structure; a first lower redistribution pattern surrounded by the lower dielectric structure; a second lower redistribution pattern on the first lower redistribution pattern; and a lower shield structure surrounded by the lower dielectric structure and surrounding the first lower redistribution pattern and the second lower redistribution pattern. The lower shield structure may include a first lower shield pattern and a second lower shield pattern on the first lower shield pattern. The first lower shield pattern may be at a level the same as a level of the first lower redistribution pattern. The second lower shield pattern may be at a level the same as a level of the second lower redistribution pattern.

In an aspect, a semiconductor package includes: a lower redistribution substrate; a first semiconductor chip mounted on the lower redistribution substrate; a connection dielectric layer that surrounds the first semiconductor chip; a connection conductive structure in the connection dielectric layer; an upper redistribution substrate on the connection dielectric layer; and a second semiconductor chip mounted on the upper redistribution substrate. The lower redistribution substrate may include: a lower dielectric structure; a lower redistribution pattern surrounded by the lower dielectric structure; and a lower shield structure surrounded by the lower dielectric structure and surrounding the lower redistribution pattern. A length of the lower shield structure may be greater than a length of the first semiconductor chip.

In an aspect, a method of fabricating a semiconductor package includes: forming a semiconductor chip; forming a connection dielectric layer that surrounds the semiconductor chip; forming a lower redistribution substrate on the semiconductor chip and the connection dielectric layer; and forming an upper redistribution substrate on the connection dielectric layer. The step of forming the lower redistribution substrate may include: forming a first lower dielectric layer on the semiconductor chip and the connection dielectric layer; forming a plurality of openings in the first lower dielectric layer; forming a conductive layer on the first lower dielectric layer; and patterning the conductive layer to form a lower redistribution pattern and a lower shield pattern. The lower shield pattern may surround the lower redistribution pattern.

### BRIEF DESCRIPTION OF THE DRAWINGS

FIG. 1A illustrates a cross-sectional view showing a semiconductor package according to some implementations.

FIG. 1B illustrates an enlarged view showing section E1 of FIG. 1A.

FIG. 1C illustrates a plan view showing a planar structure at a level L1 of FIG. 1A.

FIG. 1D illustrates a plan view showing a planar structure at a level L2 of FIG. 1A.

FIG. 1E illustrates a perspective view showing an upper shield structure.

FIG. 1F illustrates an enlarged view showing section E2 of FIG. 1A.

FIG. 1G illustrates a perspective view showing a lower shield structure.

FIGS. 2A, 2B, 2C, 2D, and 2E illustrate cross-sectional views showing a method of fabricating a semiconductor package according to some implementations.

FIG. 3 illustrates a perspective view partially showing an upper shield structure in a semiconductor package according to some implementations.

FIG. 4 illustrates an enlarged cross-sectional view showing a semiconductor package according to some implementations.

FIG. 5A illustrates an enlarged cross-sectional view showing a semiconductor package according to some implementations.

FIG. 5B illustrates a plan view showing a planar structure at a level L3 of FIG. 5A.

FIG. 6 illustrates a plan view showing a planar structure of an upper shield structure in a semiconductor package according to some implementations.

FIG. 7 illustrates a plan view showing a planar structure of an upper shield structure in a semiconductor package according to some implementations.

FIG. 8 illustrates a plan view showing a planar structure of an upper shield structure in a semiconductor package according to some implementations.

FIG. 9A illustrates a cross-sectional view showing a semiconductor package according to some implementations.

FIG. 9B illustrates a planar view showing a planar structure at a level LA of FIG. 9A.

FIG. 10 illustrates a cross-sectional view showing a semiconductor package according to some implementations.

FIG. 11 illustrates a cross-sectional view showing a semiconductor package according to some implementations.

FIG. 12 illustrates a cross-sectional view showing a semiconductor package according to some implementations.

FIG. 13 illustrates a cross-sectional view showing a semiconductor package according to some implementations.

### DETAILED DESCRIPTION

The following will describe in detail a semiconductor package and its fabrication method according to some implementations in conjunction with the accompanying drawings.

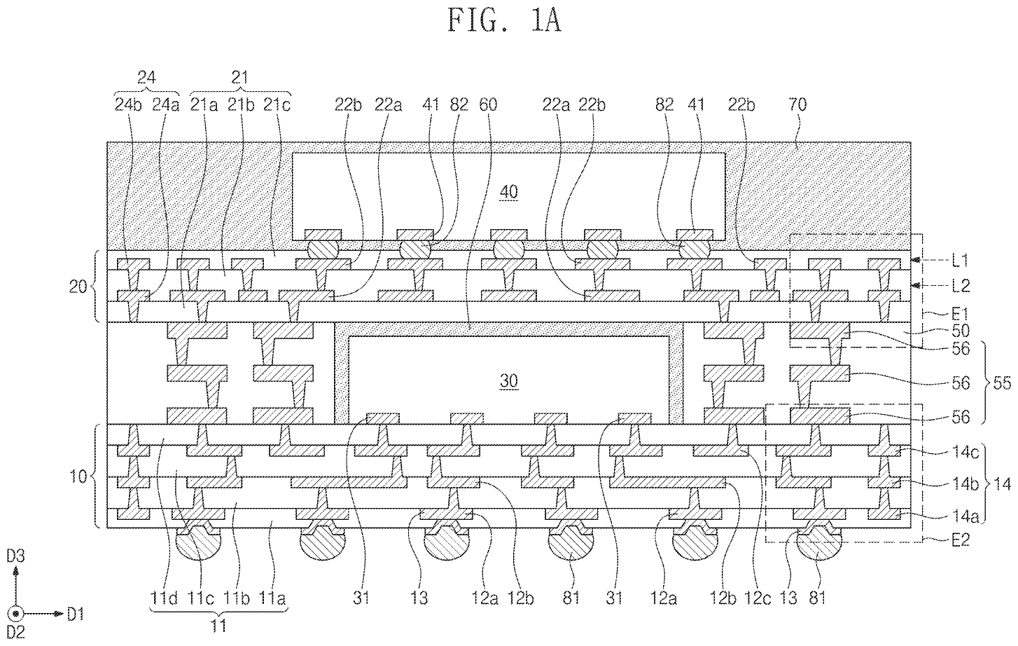

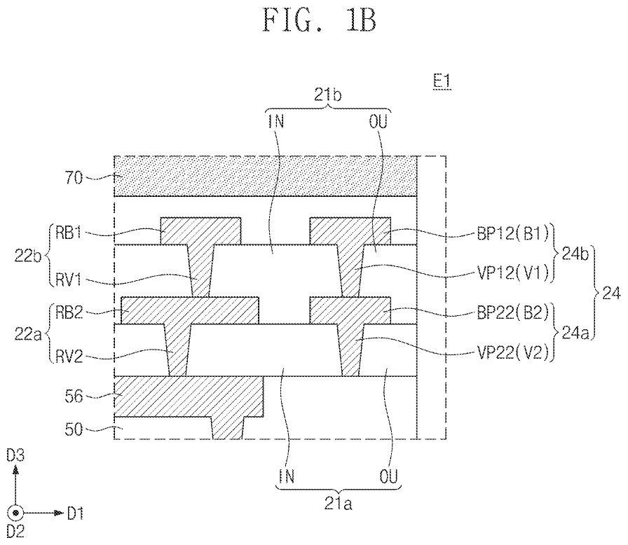

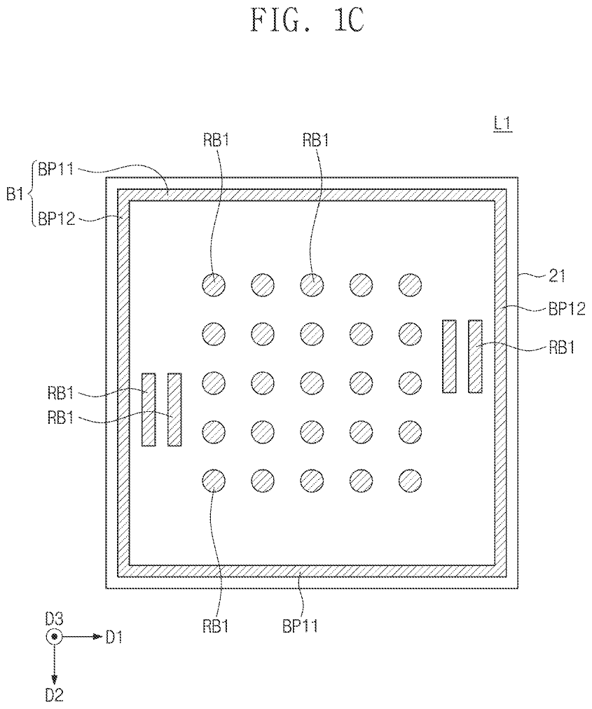

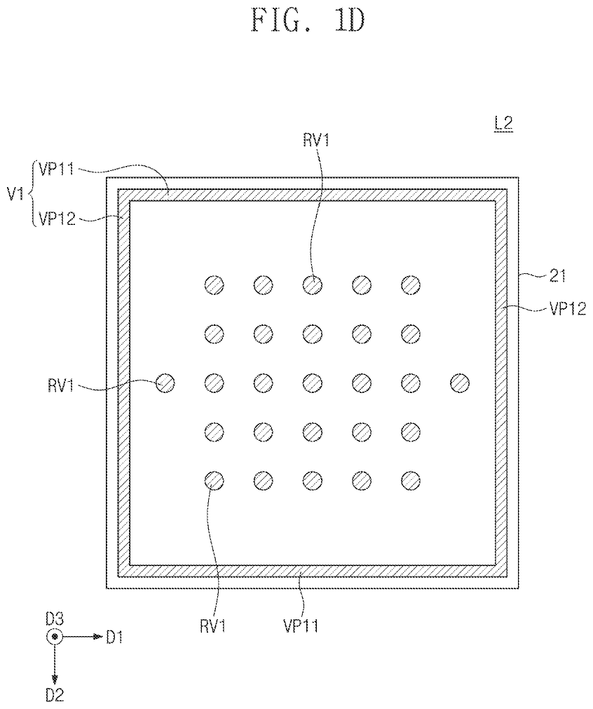

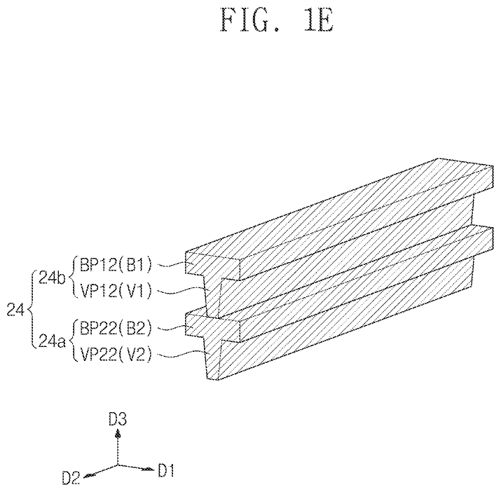

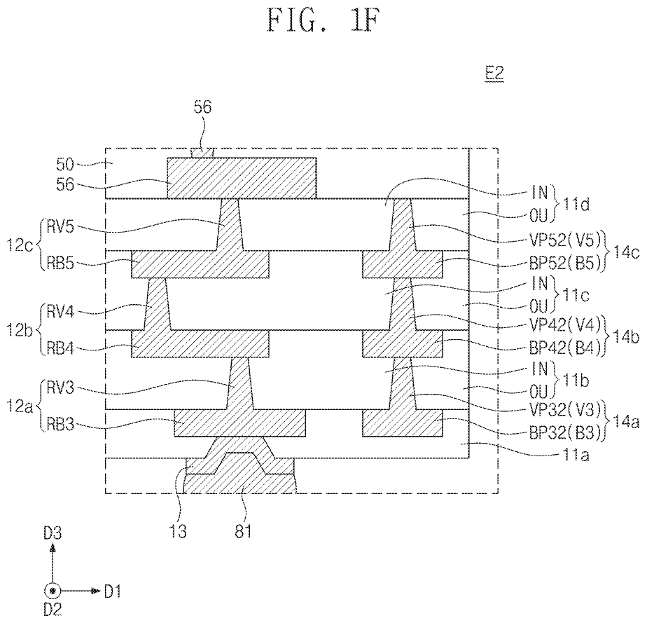

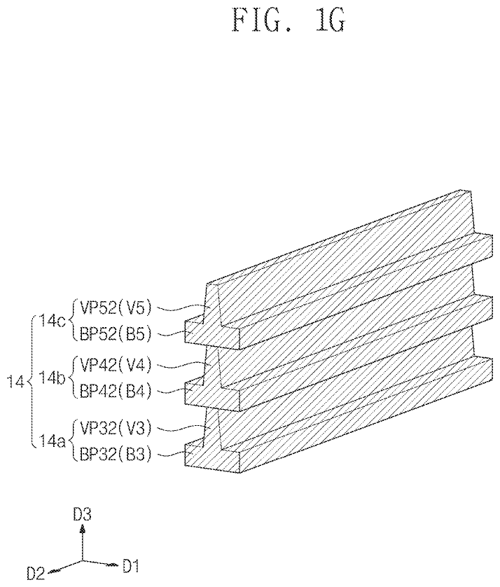

FIG. 1A illustrates a cross-sectional view showing a semiconductor package according to some implementations. FIG. 1B illustrates a plan view showing a planar structure at a level L1 of FIG. 1A. FIG. 1C illustrates a plan view showing a planar structure at a level L2 of FIG. 1A. FIG. 1D illustrates a perspective view showing an upper shield structure. FIG. 1E illustrates a perspective view showing a lower shield structure. FIG. 1F illustrates an enlarged view showing section E1 of FIG. 1A. FIG. 1G illustrates an enlarged view showing section E2 of FIG. 1A.

Referring to FIG. 1A, a semiconductor package includes a lower redistribution substrate 10, an upper redistribution substrate 20, a first semiconductor chip 30, a second semiconductor chip 40, a connection dielectric layer 50, connection conductive structures 55, a first molding layer 60, a second molding layer 70, first bumps 81, and second bumps 82.

The lower redistribution substrate 10 includes a lower dielectric structure 11, first lower redistribution patterns 12a, second lower redistribution patterns 12b, third lower redistribution patterns 12c, bump connection patterns 13, and a lower shield structure 14. The lower dielectric structure 11 includes a first lower dielectric layer 11a, a second lower dielectric layer 11b on the first lower dielectric layer 11a, a third lower dielectric layer 11c on the second lower dielectric layer 11b, and a fourth lower dielectric layer 11d on the third lower dielectric layer 11c. Each of the first, second, third, and fourth lower dielectric layers 11a, 11b, 11c, and 11d may have a plate shape that expands along a plane elongated in a first direction D1 and a second direction D2. The first direction D1 and the second direction D2 may intersect each other. For example, the first direction D1 and the second direction D2 may be horizontal directions that are orthogonal to each other.

The first, second, third, and fourth lower dielectric layers 11a, 11b, 11c, and 11d may be sequentially stacked along a third direction D3. The third direction D3 may intersect the first direction D1 and the second direction D2. For example, the third direction D3 may be a vertical direction perpendicular to the first direction D1 and the second direction D2.

The first lower dielectric layer 11a may include a dielectric material. For example, the first lower dielectric layer 11a may include a photo-imagable dielectric (PID) or an ajinomoto buildup film (ABF). The photo-imagable dielectric may include, for example, at least one selected from photosensitive polyimide, polybenzoxazole, phenolic polymers, and benzocyclobutene polymers.

The second, third, and fourth lower dielectric layers 11b, 11c, and 11d may include a dielectric material. For example, the second, third, and fourth lower dielectric layers 11b, 11c, and 11d may include a photo-imagable dielectric.

The first, second, and third lower redistribution patterns 12a, 12b, and 12c may be surrounded by the first, second, third, and fourth lower dielectric layers 11a, 11b, 11c, and 11d of the lower dielectric structure 11. The first, second, and third lower redistribution patterns 12a, 12b, and 12c may be disposed in the first, second, third, and fourth lower dielectric layers 11a, 11b, 11c, and 11d of the lower dielectric structure 11.

The second lower redistribution patterns 12b may be provided on the first lower redistribution patterns 12a. The third lower redistribution patterns 12c may be provided on the second lower redistribution patterns 12b. The second lower redistribution patterns 12b may be located at a higher level than that of the first lower redistribution patterns 12a. The third lower redistribution patterns 12c may be located at a higher level than that of the second lower redistribution patterns 12b.

The first, second, and third lower redistribution patterns 12a, 12b, and 12c may include a conductive material. For example, the first, second, and third lower redistribution patterns 12a, 12b, and 12c may include copper.

The bump connection pattern 13 may be connected to the first lower redistribution patterns 12a. The bump connection pattern 13 may be outwardly exposed from the lower dielectric structure 11. The bump connection pattern 13 may include a conductive material. For example, the bump connection pattern 13 may include copper.

The lower shield structure 14 may surround the first, second, and third lower redistribution patterns 12a, 12b, and 12c. The lower shield structure 14 may be surrounded by the first, second, third, and fourth lower dielectric layers 11a, 11b, 11c, and 11d of the lower dielectric structure 11. The lower shield structure 14 may be disposed in the first, second, third, and fourth lower dielectric layers 11a, 11b, 11c, and 11d of the lower dielectric structure 11.

The lower shield structure 14 may be disposed on an outer region of the lower redistribution substrate 10. The first, second, and third lower redistribution patterns 12a, 12b, and 12c and the bump connection patterns 13 may be disposed on an inner region of the lower redistribution substrate 10. The inner region of the lower redistribution substrate 10 may be closer than the outer region of the lower redistribution substrate 10 to a center of the lower redistribution substrate 10. The outer region of the lower redistribution substrate 10 may surround the inner region of the lower redistribution substrate 10.

The lower shield structure 14 includes a first lower shield pattern 14a, a second lower shield pattern 14b on the first lower shield pattern 14a, and a third lower shield pattern 14c on the second lower shield pattern 14b. The second lower shield pattern 14b may be located at a higher level than that of the first lower shield pattern 14a. The third lower shield pattern 14c may be located at a higher level than that of the second lower shield pattern 14b. The first lower shield pattern 14a may be located at the same level as that of the first lower redistribution patterns 12a. The second lower shield pattern 14b may be located at the same level as that of the second lower redistribution patterns 12b. The third lower shield pattern 14c may be located the same level as that of the third lower redistribution patterns 12c.

The first, second, and third lower shield patterns 14a, 14b, and 14c may include the same material as that of the first, second, and third lower redistribution patterns 12a, 12b, and 12c. For example, the first, second, and third lower shield patterns 14a, 14b, and 14c may include copper.

The first bump 81 may be connected to the bump connection pattern 13. The semiconductor package may be electrically connected through the first bumps 81 to an external apparatus. The first bumps 81 may include a conductive material.

The first semiconductor chip 30 may be provided on the lower redistribution substrate 10. The first semiconductor chip 30 may include at least one selected from a semiconductor substrate, a dielectric substrate, a silicon-on-insulator (SOI) substrate, or a germanium-on-insulator (GOI) substrate. In some implementations, the first semiconductor chip 30 may be a logic chip including a logic semiconductor device, a memory chip including a memory semiconductor device, an image sensor chip including an image sensor device, or a modem chip.

The first semiconductor chip 30 includes first pads 31. The first pad 31 may be in contact with the third lower redistribution pattern 12c. The first pad 31 may include a conductive material. For example, the first pad 31 may include copper.

The first semiconductor chip 30 may be mounted on the lower redistribution substrate 10. The first semiconductor chip 30 may be electrically connected to the lower redistribution substrate 10. The first semiconductor chip 30 may have a bottom surface in contact with a top surface of the lower redistribution substrate 10. In some implementations, a bump may be provided between the first semiconductor chip 30 and the lower redistribution substrate 10, and the first semiconductor chip 30 and the lower redistribution substrate 10 may be electrically connected through the bump.

The connection dielectric layer 50 may be provided on the lower redistribution substrate 10. The connection dielectric layer 50 may have a bottom surface in contact with the top surface of the lower redistribution substrate 10. The connection dielectric layer 50 may surround the first semiconductor chip 30. The connection dielectric layer 50 may include a polymeric material. For example, the connection dielectric layer 50 may include at least one selected from phenolic resin, epoxy resin, and polyimide. In some implementations, the connection dielectric layer 50 may be a multiple layer including a plurality of dielectric layers.

The connection dielectric layer 50 may be provided with connection conductive structures 55 therein. The connection dielectric layer 50 may surround each connection conductive structure 55. The connection conductive structures 55 includes connection conductive patterns 56 that overlap each other along the third direction D3. The connection conductive structures 55 may be in contact with the third lower redistribution patterns 12c. The connection conductive patterns 56 may include a conductive material. For example, the connection conductive patterns 56 may include copper.

A distance between the lower shield structure 14 and the first semiconductor chip 30 may be greater than a distance between the connection conductive structures 55 and the first semiconductor chip 30. For example, a distance in the first direction D1 between the lower shield structure 14 and the first semiconductor chip 30 may be greater than a distance in the first direction D1 between the connection conductive structures 55 and the first semiconductor chip 30. The distance between the lower shield structure 14 and the first semiconductor chip 30 may be greater than a distance between the lower redistribution patterns 12a, 12b, and 12c and the first semiconductor chip 30. For example, the distance in the first direction D1 between the lower shield structure 14 and the first semiconductor chip 30 may be greater than a distance in the first direction D1 between the lower redistribution patterns 12a, 12b, and 12c and the first semiconductor chip 30. A distance between an outer sidewall of the lower dielectric structure 11 and the lower shield structure 14 may be less than a distance between the outer sidewall of the lower dielectric structure 11 and the lower redistribution patterns 12a, 12b, and 12c. For example, a distance in the first direction D1 between the outer sidewall of the lower dielectric structure 11 and the lower shield structure 14 may be less than a distance in the first direction D1 between the outer sidewall of the lower dielectric structure 11 and the lower redistribution patterns 12a, 12b, and 12c.

The first molding layer 60 may be provided between the first semiconductor chip 30 and the connection dielectric layer 50. The first molding layer 60 may cover a sidewall and a top surface of the first semiconductor chip 30. The first molding layer 60 may include a polymeric material. For example, the first molding layer 60 may include an epoxy resin.

The upper redistribution substrate 20 may be provided on the first molding layer 60 and the connection dielectric layer 50. The upper redistribution substrate 20 includes an upper dielectric structure 21, first upper redistribution patterns 22a, second upper redistribution patterns 22b, and an upper shield structure 24.

The upper dielectric structure 21 includes a first upper dielectric layer 21a, a second upper dielectric layer 21b on the first upper dielectric layer 21a, and a third upper dielectric layer 21c on the second upper dielectric layer 21b. The first, second, and third upper dielectric layers 21a, 21b, and 21c may be sequentially stacked along the third direction D3.

The first and second upper dielectric layers 21a and 21b may include a dielectric material. For example, the first and second upper dielectric layers 21a and 21b may include a photo-imagable dielectric. The third upper dielectric layer 21c may include a dielectric material. For example, the third upper dielectric layer 21c may include a photo-imagable dielectric (PID) or an ajinomoto buildup film (ABF).

The first and second upper redistribution patterns 22a and 22b may be surrounded by the first, second, and third upper dielectric layers 21a, 21b, and 21c of the upper dielectric structure 21. The first and second upper redistribution patterns 22a and 22b may be disposed in the first, second, and third upper dielectric layers 21a, 21b, and 21c of the upper dielectric structure 21.

The second upper redistribution patterns 22b may be provided on the first upper redistribution patterns 22a. The second upper redistribution patterns 22b may be located at a higher level than that of the first upper redistribution patterns 22a. The first and second upper redistribution patterns 22a and 22b may include a conductive material. For example, the first and second upper redistribution patterns 22a and 22b may include copper.

The upper shield structure 24 may surround the first and second upper redistribution patterns 22a and 22b. The upper shield structure 24 may be surrounded by the first, second, and third upper dielectric layers 21a, 21b, and 21c of the upper dielectric structure 21. The upper shield structure 24 may be disposed in the first, second, and third upper dielectric layers 21a, 21b, and 21c of the upper dielectric structure 21.

The upper shield structure 24 may be disposed on an outer region of the upper redistribution substrate 20. The first and second upper redistribution patterns 22a and 22b may be disposed on an inner region of the upper redistribution substrate 20. The outer region of the upper redistribution substrate 20 may surround the inner region of the upper redistribution substrate 20.

The upper shield structure 24 includes a first upper shield pattern 24a and a second upper shield pattern 24b on the first upper shield pattern 24a. The second upper shield pattern 24b may be located at a higher level than that of the first upper shield patterns 24a. The first upper shield pattern 24a may be located at the same level as that of the first upper redistribution patterns 22a. The second upper shield pattern 24b may be located at the same level as that of the second upper redistribution patterns 22b.

The first and second upper shield patterns 24a and 24b may include the same material as that of the first and second upper redistribution patterns 22a and 22b. For example, the first and second upper shield patterns 24a and 24b may include copper.

The first and second upper shield patterns 24a and 24b of the upper shield structure 24 may overlap in the third direction D3 with the first, second, and third lower shield patterns 14a, 14b, and 14c of the lower shield structure 14.

A distance between the upper shield structure 24 and the first semiconductor chip 30 may be greater than a distance between the connection conductive structures 55 and the first semiconductor chip 30. For example, a distance in the first direction D1 between the upper shield structure 24 and the first semiconductor chip 30 may be greater than a distance in the first direction D1 between the connection conductive structures 55 and the first semiconductor chip 30. The distance between the upper shield structure 24 and the first semiconductor chip 30 may be greater than a distance between the upper redistribution patterns 22a and 22b and the first semiconductor chip 30. For example, the distance in the first direction D1 between the upper shield structure 24 and the first semiconductor chip 30 may be greater than a distance in the first direction D1 between the upper redistribution patterns 22a and 22b and the first semiconductor chip 30. A distance between an outer sidewall of the upper dielectric structure 21 and the upper shield structure 24 may be less than a distance between the outer sidewall of the upper dielectric structure 21 and the upper redistribution patterns 22a and 22b. For example, a distance in the first direction D1 between the outer sidewall of the upper dielectric structure 21 and the upper shield structure 24 may be less than a distance in the first direction D1 between the outer sidewall of the upper dielectric structure 21 and the upper redistribution patterns 22a and 22b.

The second semiconductor chip 40 may be mounted on the upper redistribution substrate 20. The second semiconductor chip 40 may be electrically connected to the upper redistribution substrate 20. The second semiconductor chip 40 may include at least one selected from a semiconductor substrate, a dielectric substrate, a silicon-on-insulator (SOI) substrate, or a germanium-on-insulator (GOI) substrate. In some implementations, the second semiconductor chip 40 may be a logic chip including a logic semiconductor device, a memory chip including a memory semiconductor device, an image sensor chip including an image sensor device, or a modem chip.

The second semiconductor chip 40 includes second pads 41. The second pads 41 may include a conductive material. For example, the second pads 41 may include copper.

The second bumps 82 may be provided between the second semiconductor chip 40 and the upper redistribution substrate 20. The second bumps 82 may be in contact with the second upper redistribution patterns 22b and the second pads 41. The second semiconductor chip 40 may be electrically connected through the second bumps 82 to the upper redistribution substrate 20. The second bumps 82 may include a conductive material.

The second molding layer 70 may be provided to surround the second semiconductor chip 40. The second molding layer 70 may cover a sidewall and a top surface of the second semiconductor chip 40. The second molding layer 70 may cover a top surface of the upper redistribution substrate 20. The second molding layer 70 may include a polymeric material. For example, the second molding layer 70 may include an epoxy resin.

Referring to FIGS. 1B, 1C, 1D, and 1E, the second upper shield pattern 24b includes a shield via part V1 and a shield base part B1. The shield base part B1 of the second upper shield pattern 24b may be provided on the shield via part V1 of the second upper shield pattern 24b. Although described separately for convenience, the shield via part V1 and the shield base part B1 of the second upper shield pattern 24b may be connected into a single unitary structure with no boundary therebetween.

The shield via part V1 of the second upper shield pattern 24b includes first portions VP11 that extend in the first direction D1 and second portions VP12 that extend in the second direction D2. The first portions VP11 of the shield via part V1 included in the second upper shield pattern 24b may have a linear shape in which a length in the first direction D1 is greater than a length in the second direction D2. A length in the first direction D1 of the first portions VP11 of the shield via part V1 included in the second upper shield pattern 24b may be greater than a length in the first direction D1 of the first semiconductor chip 30. The second portions VP12 of the shield via part V1 included in the second upper shield pattern 24b may have a linear shape in which a length in the second direction D2 is greater than a length in the first direction D1. A length in the second direction D2 of the second portions VP12 of the shield via part V1 included in the second upper shield pattern 24b may be greater than a length in the second direction D2 of the first semiconductor chip 30.

The first portions VP11 of the shield via part V1 included in the second upper shield pattern 24b may be spaced apart from each other in the second direction D2. The second portions VP12 of the shield via part V1 included in the second upper shield pattern 24b may be spaced apart from each other in the first direction D1. The first portions VP11 of the shield via part V1 included in the second upper shield pattern 24b may be connected to two second portions VP12 of the shield via part V1 included in the second upper shield pattern 24b.

The shield base part B1 of the second upper shield pattern 24b includes first portions BP11 that extend in the first direction D1 and second portions BP12 that extend in the second direction D2. The first portions BP11 of the shield base part B1 included in the second upper shield pattern 24b may have a linear shape in which a length in the first direction D1 is greater than a length in the second direction D2. A length in the first direction D1 of the first portions BP11 of the shield base part B1 included in the second upper shield pattern 24b may be greater than the length in the first direction D1 of the first semiconductor chip 30. The second portions BP12 of the shield base part B1 included in the second upper shield pattern 24b may have a linear shape in which a length in the second direction D2 is greater than a length in the first direction D1. A length in the second direction D2 of the second portions BP12 of the shield base part B1 included in the second upper shield pattern 24b may be greater than the length in the second direction D2 of the first semiconductor chip 30.

The first portions BP11 of the shield base part B1 included in the second upper shield pattern 24b may be spaced apart from each other in the second direction D2. The second portions BP12 of the shield base part B1 included in the second upper shield pattern 24b may be spaced apart from each other in the first direction D1. The first portions BP11 of the shield base part B1 included in the second upper shield pattern 24b may be connected to the second portions BP12 of the shield base part B1 included in the second upper shield pattern 24b.

Each second upper redistribution pattern 22b includes a redistribution via part RV1 and a redistribution base part RB1. The redistribution base part RB1 of the second upper redistribution pattern 22b may be provided on the redistribution via part RV1 of the second upper redistribution pattern 22b. The redistribution base part RB1 of the second upper redistribution pattern 22b may have a width less than that of the redistribution via part RV1 of the second upper redistribution pattern 22b. For example, when viewed in vertical section as shown in FIG. 1B, a width in the first direction D1 of the redistribution via part RV1 included in the second upper redistribution pattern 22b may be less than a width in the first direction D1 of the redistribution base part RB1 included in the second upper redistribution pattern 22b.

A width of the redistribution via part RV1 included in the second upper redistribution pattern 22b may decrease with decreasing level. The width of the redistribution via part RV1 included in the second upper redistribution pattern 22b may decrease with decreasing distance from the lower redistribution substrate 10.

The redistribution via part RV1 of the second upper redistribution pattern 22b may be located at the same level as that of the shield via part V1 of the second upper shield pattern 24b. The redistribution via part RV1 of the second upper redistribution pattern 22b may have a bottom surface at a lower level than that of a bottom surface of the shield via part V1 of the second upper shield pattern 24b. The bottom surface of the redistribution via part RV1 included in the second upper redistribution pattern 22b may be coplanar with the bottom surface of the shield via part V1 included in the second upper shield pattern 24b.

The redistribution base part RB1 of the second upper redistribution pattern 22b may be located at the same level as that of the shield base part B1 of the second upper shield pattern 24b. The redistribution base part RB1 of the second upper redistribution pattern 22b may have a top surface at the same level as that of a top surface of the shield base part B1 of the second upper shield pattern 24b. The top surface of the redistribution base part RB1 included in the second upper redistribution pattern 22b may be coplanar with the top surface of the shield base part B1 included in the second upper shield pattern 24b.

A length in the third direction D3 of the redistribution via part RV1 included in each second upper redistribution pattern 22b may be the same as a length in the third direction D3 of the shield via part V1 included in the second upper shield pattern 24b. The length in the third direction D3 of the redistribution via part RV1 included in the second upper redistribution pattern 22b may be the same as a length in the third direction D3 of the shield base part B1 included in the second upper shield pattern 24b. A length in the third direction D3 of the second upper redistribution pattern 22b may be the same as a length in the third direction D3 of the second upper shield pattern 24b.

When viewed in plan as shown in FIG. 1C, the redistribution base parts RB1 of the second upper redistribution patterns 22b may have a circular or bar shape, and the shield base part B1 of the second upper shield pattern 24b may have a tetragonal ring shape. The shield base part B1 of the second upper shield pattern 24b may surround the redistribution base parts RB1 of the second upper redistribution patterns 22b. The redistribution base parts RB1 of the second redistribution patterns 22b may be disposed between the first portions BP11 of the shield base parts B1 included in the second upper shield pattern 24b. The redistribution base parts RB1 of the second redistribution patterns 22b may be disposed between the second portions BP12 of the shield base parts B1 included in the second upper shield pattern 24b.

When viewed in plan as shown in FIG. 1D, the redistribution via parts RV1 of the second upper redistribution patterns 22b may have a circular shape, and the shield via part V1 of the second upper shield pattern 24b may have a tetragonal ring shape. The shield via part V1 of the second upper shield pattern 24b may surround the redistribution via parts RV1 of the second upper redistribution patterns 22b. The redistribution via parts RV1 of the second upper redistribution patterns 22b may be disposed between the first portions VP11 of the shield via part V1 included in the second upper shield pattern 24b. The redistribution via parts RV1 of the second upper redistribution patterns 22b may be disposed between the second portions VP12 of the shield via part V1 included in the second upper shield pattern 24b.

Referring to FIGS. 1B to 1E, the shield via part V1 of the second upper shield pattern 24b may have a width less than that of the shield base part B1 of the second upper shield pattern 24b. For example, a width in the first direction D1 of each second portion VP12 of the shield via part V1 included in the second upper shield pattern 24b may be less than a width in the first direction D1 of each second portion BP12 of the shield base part B1 included in the second upper shield pattern 24b. The shield via part V1 of the second upper shield pattern 24b may have a width that decreases with decreasing level. The width of the shield via part V1 included in the second upper shield pattern 24b may decrease with decreasing distance from the lower redistribution substrate 10. For example, a width in the first direction D1 of each shield via part RV1 included in the second upper shield pattern 24b may decrease with decreasing distance from the lower redistribution substrate 10.

The width in the first direction D1 of each shield via part RV1 included in the second upper shield pattern 24b may range, for example, from about 10 μm to about 50 μm. A width in the first direction D1 of each second portion BP12 of the shield base part B1 included in the second upper shield pattern 24b may range, for example, from about 20 μm to about 100 μm.

The first upper shield pattern 24a includes a shield via part V2 and a shield base part B2. The shield base part B2 of the first upper shield pattern 24a may be provided on the shield via part V2 of the first upper shield pattern 24a.

Similar to the shield via part V1 of the second upper shield pattern 24b, the shield via part V2 of the first upper shield pattern 24a may have a tetragonal ring shape. The shield via part V2 of the first upper shield pattern 24a may include first portions that extend in the first direction D1 and second portions VP22 that extend in the second direction D2.

Similar to the shield base part B1 of the second upper shield pattern 24b, the shield base part B2 of the first upper shield pattern 24a may have a tetragonal ring shape. The shield base part B2 of the first upper shield pattern 24a may include first portions that extend in the first direction D1 and second portions BP52 that extend in the second direction D2.

The shield via part V2 of the first upper shield pattern 24a may have a width less than that of the shield base part B2 of the first upper shield pattern 24a. The width of the shield via part V2 included in the first upper shield pattern 24a may decrease with decreasing level.

The shield via part V2 of the first upper shield pattern 24a may overlap in the third direction D3 with the shield via part V1 of the second upper shield pattern 24b. The second portions VP22 of the shield via part V2 included in the first upper shield pattern 24a may overlap in the third direction D3 with the second portions VP12 of the shield via part V1 included in the second upper shield pattern 24b.

Each first upper redistribution pattern 22a may include a redistribution via part RV2 and a redistribution base part RB2. The redistribution base part RB2 of the first upper redistribution pattern 22a may be provided on the redistribution via part RV2 of the first upper redistribution pattern 22a. The redistribution via part RV2 of the first upper redistribution pattern 22a may have a width less than that of the redistribution base part RB2 of the first upper redistribution pattern 22a. The width of the redistribution via part RV2 included in the first upper redistribution pattern 22a may decrease with decreasing level.

The redistribution via part RV2 of the first upper redistribution pattern 22a may be located at the same level as that of the shield via part V2 of the first upper shield pattern 24a. The redistribution base part RB2 of the first upper redistribution pattern 22a may be located at the same level as that of the shield base part B2 of the first upper shield pattern 24a.

The shield base part B2 of the first upper shield pattern 24a may surround the redistribution base parts RB2 of the first upper redistribution pattern 22a. The shield via part V2 of the first upper shield pattern 24a may surround the redistribution via parts RV2 of the first upper redistribution pattern 22a.

Each of the first and second upper dielectric layers 21a and 21b includes an inner part IN surrounded by the upper shield structure 24 and an outer part OU that surrounds the upper shield structure 24. The upper shield structure 24 may separate from each other the inner part IN and the outer part OU of each of the first and second upper dielectric layers 21a and 21b. The inner part IN and the outer part OU of the first upper dielectric layer 21a may be spaced apart from each other across the shield via part V2 of the first upper shield pattern 24a. The inner part IN and the outer part OU of the second upper dielectric layer 21b may be spaced apart from each other across the shield base part B2 of the first upper shield pattern 24a and the shield via part V1 of the second upper shield pattern 24b.

The upper shield structure 24 may have a tetragonal ring shape. The upper shield structure 24 may include first portions that extend in the first direction D1 and second portions that extend in the second direction D2. The first portions of the upper shield structure 24 may include the first portions of the shield via part V2 and the shield base part B2 included in the first upper shield pattern 24a, and may also include the first portions VP11 and BP11 of the shield via part V1 and the shield base part B1 included in the second upper shield pattern 24b. The second portions of the upper shield structure 24 may include the second portions VP22 and BP22 of the shield via part V2 and the shield base part B2 included in the first upper shield pattern 24a, and may also include the second portions VP12 and BP12 of the shield via part V1 and the shield base part B1 included in the second upper shield pattern 24b.

A length in the first direction D1 of the first portions included in the upper shield structure 24 may be greater than the length in the first direction D1 of the first semiconductor chip 30. A length in the second direction D2 of the second portions included in the upper shield structure 24 may be greater than the length in the second direction D2 of the first semiconductor chip 30.

The first and second upper redistribution patterns 22a and 22b may be disposed between the first portions of the upper shield structure 24. The first and second upper redistribution patterns 22a and 22b may be disposed between the second portions of the upper shield structure 24.

Referring to FIGS. 1F and 1G, each first lower shield pattern 14a includes a shield via part V3 and a shield base part B3. The shield via part V3 of the first lower shield pattern 14a may be provided on the shield base part B3 of the first lower shield pattern 14a.

Similar to the shield via part V1 of the second upper shield pattern 24b, the shield via part V3 of the first lower shield pattern 14a may have a tetragonal ring shape. The shield via part V3 of the first lower shield pattern 14a may include first portions that extend in the first direction D1 and second portions VP32 that extend in the second direction D2.

Similar to the shield base part B1 of the second upper shield pattern 24b, the shield base part B3 of the first lower shield pattern 14a may have a tetragonal ring shape. The shield base part B3 of the first lower shield pattern 14a may include first portions that extend in the first direction D1 and second portions BP32 that extend in the second direction D2.

The shield via part V3 of the first lower shield pattern 14a may have a width less than that of the shield base part B3 of the first lower shield pattern 14a. The width of the shield via part V3 included in the first lower shield pattern 14a may decrease with increasing level. The width of the shield via part V3 included in the first lower shield pattern 14a may decrease with decreasing distance from the upper redistribution substrate 20.

Each first lower redistribution pattern 12a includes a redistribution via part RV3 and a redistribution base part RB3. The redistribution via part RV3 of the first lower redistribution pattern 12a may be provided on the redistribution base part RB3 of the first lower redistribution pattern 12a. The redistribution via part RV3 of the first lower redistribution pattern 12a may have a width less than that of the redistribution base part RB3 of the first lower redistribution pattern 12a. The width of the redistribution via part RV3 included in the first lower redistribution pattern 12a may decrease with increasing level.

The redistribution via part RV3 of each first lower redistribution pattern 12a may be located at the same level as that of the shield via part V3 of the first lower shield pattern 14a. The redistribution base part RB3 of each first lower redistribution pattern 12a may be located at the same level as that of the shield base part B3 of the first lower shield pattern 14a.

The shield base part B3 of the first lower shield pattern 14a may surround the redistribution base parts RB3 of the first lower redistribution pattern 12a. The shield via part V3 of the first lower shield pattern 14a may surround the redistribution via parts RV3 of the first lower redistribution pattern 12a.

The second lower shield pattern 14b includes a shield via part V4 and a shield base part B4. The shield via part V4 of the second lower shield pattern 14b may be provided on the shield base part B4 of the second lower shield pattern 14b.

Similar to the shield via part V1 of the second upper shield pattern 24b, the shield via part V4 of the second lower shield pattern 14b may have a tetragonal ring shape. The shield via part V4 of the second lower shield pattern 14b may include first portions that extend in the first direction D1 and second portions VP42 that extend in the second direction D2.

Similar to the shield base part B1 of the second upper shield pattern 24b, the shield base part B4 of the second lower shield pattern 14b may have a tetragonal ring shape. The shield base part B4 of the second lower shield pattern 14b may include first portions that extend in the first direction D1 and second portions BP42 that extend in the second direction D2.

The second lower redistribution pattern 12b includes a redistribution via part RV4 and a redistribution base part RB4. The redistribution via part RV4 of the second lower redistribution pattern 12b may be provided on the redistribution base part RB4 of the second lower redistribution pattern 12b.

The redistribution via part RV4 of each second lower redistribution pattern 12b may be located at the same level as that of the shield via part V4 of the second lower shield pattern 14b. The redistribution base part RB4 of each second lower redistribution pattern 12b may be located at the same level as that of the shield base part B4 of the second lower shield pattern 14b.

The shield base part B4 of the second lower shield patterns 14b may surround the redistribution base parts RB4 of the second lower redistribution patterns 12b. The shield via part V4 of the second lower shield patterns 14b may surround the redistribution via parts RV4 of the second lower redistribution patterns 12b.

Each third lower shield pattern 14c includes a shield via part V5 and a shield base part B5. The shield via part V5 of the third lower shield pattern 14c may be provided on the shield base part B5 of the third lower shield pattern 14c.

Similar to the shield via part V1 of the second upper shield pattern 24b, the shield via part V5 of the third lower shield pattern 14c may have a tetragonal ring shape. The shield via part V5 of the third lower shield pattern 14c may include first portions that extend in the first direction D1 and second portions VP52 that extend in the second direction D2.

Similar to the shield base part B1 of the second upper shield pattern 24b, the shield base part B5 of the third lower shield pattern 14c may have a tetragonal ring shape. The shield base part B5 of the third lower shield pattern 14c may include first portions that extend in the first direction D1 and second portions BP52 that extend in the second direction D2.

Each third lower redistribution pattern 12c includes a redistribution via part RV5 and a redistribution base part RB5. The redistribution via part RV5 of the third lower redistribution pattern 12c may be provided on the redistribution base part RB5 of the third lower redistribution pattern 12c.

The redistribution via part RV5 of each third lower redistribution pattern 12c may be located at the same level as that of the shield via part V5 of the third lower shield pattern 14c. The redistribution base part RB5 of each third lower redistribution pattern 12c may be located at the same level as that of the shield base part B5 of the third lower shield pattern 14c.

The shield base part B5 of the third lower shield patterns 14c may surround the redistribution base parts RB5 of the third lower redistribution patterns 12c. The shield via part V5 of the third lower shield patterns 14c may surround the redistribution via parts RV5 of the third lower redistribution patterns 12c.

The shield via part V3 of each first lower shield pattern 14a, the shield via part V4 of each second lower shield pattern 14b, and the shield via part V5 of each third lower shield pattern 14c may overlap each other in the third direction D3. The second portions VP32 of the shield via part V3 included in the first lower shield patterns 14a, the second portions VP42 of the shield via part V4 included in the second lower shield patterns 14b, and the second portions VP52 of the shield via part V5 included in the third lower shield patterns 14c may overlap each other in the third direction D3.

In some implementations, the shield via parts V3, V4, and V5 of the first, second, and third lower shield patterns 14a, 14b, and 14c may overlap in the third direction D3 with the shield via parts V2 and V1 of the first and second upper shield patterns 24a and 24b.

Each of the second, third, and fourth lower dielectric layers 11b, 11c, and 11d includes an inner part IN surrounded by the lower shield structure 14 and an outer part OU that surrounds the lower shield structure 14. The lower shield structure 14 may separate from each other the inner part IN and the outer part OU of each of the second, third, and fourth lower dielectric layers 11b, 11c, and 11d. The inner part IN and the outer part OU of the second lower dielectric layer 11b may be spaced apart from each other across the shield via part V3 of the first lower shield pattern 14a and the shield base part B4 of the second lower shield pattern 14b. The inner part IN and the outer part OU of the third lower dielectric layer 11c may be spaced apart from each other across the shield via part V4 of the second lower shield pattern 14b and the shield base part B5 of the third lower shield pattern 14c. The inner part IN and the outer part OU of the fourth lower dielectric layer 11d may be spaced apart from each other across the shield via part V5 of the third lower shield pattern 14c.

The lower shield structure 14 may have a tetragonal ring shape. The lower shield structure 14 may include first portions that extend in the first direction D1 and second portions that extend in the second direction D2. The first portions of the lower shield structure 14 may include the first portions of the shield via part V3 and the shield base part B3 included in the first lower shield pattern 14a, the first portions of the shield via part V4 and the shield base part B4 included in the second lower shield pattern 14b, and the first portions of the shield via part V5 and the shield base part B5 included in the third lower shield pattern 14c. The second portions of the lower shield structure 14 may include the second portions VP32 and BP32 of the shield via part V3 and the shield base part B3 included in the first lower shield pattern 14a, the second portions VP42 and BP42 of the shield via part V4 and the shield base part B4 included in the second lower shield pattern 14b, and the second portions VP52 and BP52 of the shield via part V5 and the shield base part B5 included in the third lower shield pattern 14c.

The first, second, and third lower redistribution patterns 12a, 12b, and 12c may be disposed between the first portions of the lower shield structure 14. The first, second, and third lower redistribution patterns 12a, 12b, and 12c may be disposed between the second portions of the lower shield structure 14.

In a semiconductor package according to some implementations, the lower shield structure 14 and the upper shield structure 24 may serve as a crack stopper, and thus the semiconductor package may improve in stiffness and may be protected against external forces.

In a semiconductor package according to some implementations, the lower shield structure 14 and the upper shield structure 24 may block electromagnetic waves.

In a semiconductor package according to some implementations, warpage of the lower redistribution substrate 10 may be changed depending on size of the lower shield structure 14, and warpage of the upper redistribution substrate 20 may be changed depending on size of the upper shield structure 24. Therefore, the sizes of the lower and upper shield structures 14 and 24 may be adjusted to minimize the warpage of the lower and upper redistribution substrates 10 and 20.

A semiconductor package according to some implementations includes the lower shield structure 14 and the upper shield structure 24, and it may thus be possible to improve a reduction in thickness of the lower dielectric structure 11 and the upper dielectric structure 21 in a process for forming the lower dielectric structure 11 and the upper dielectric structure 21.

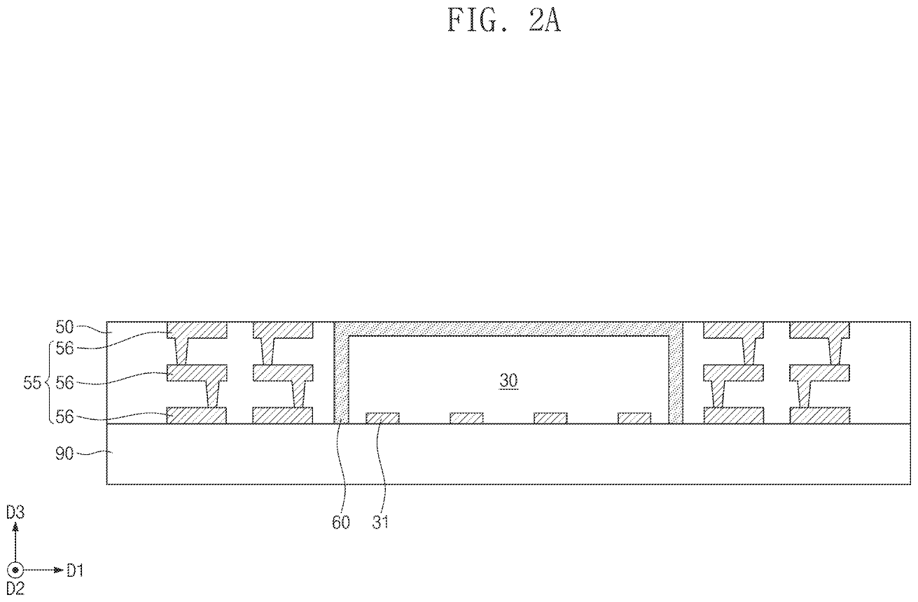

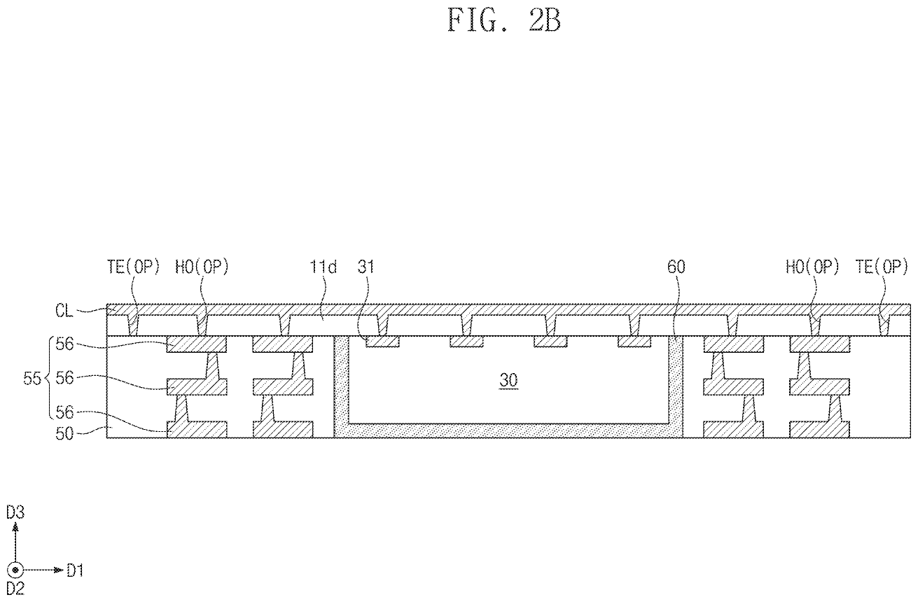

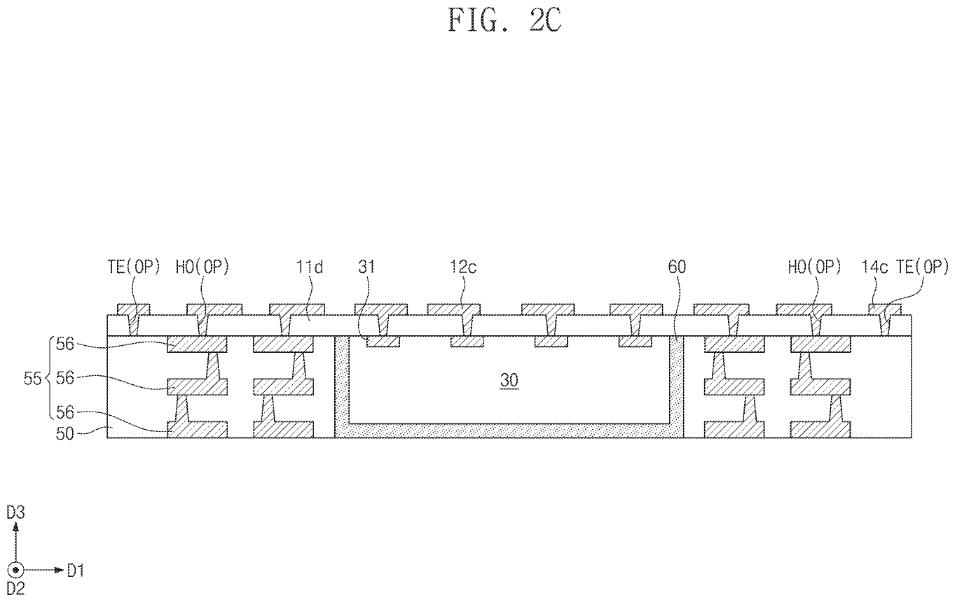

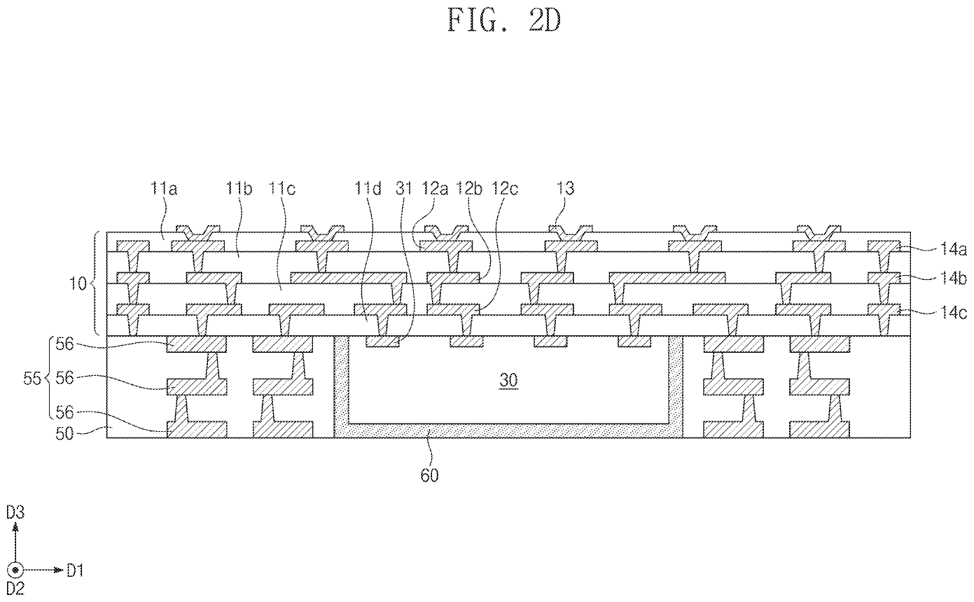

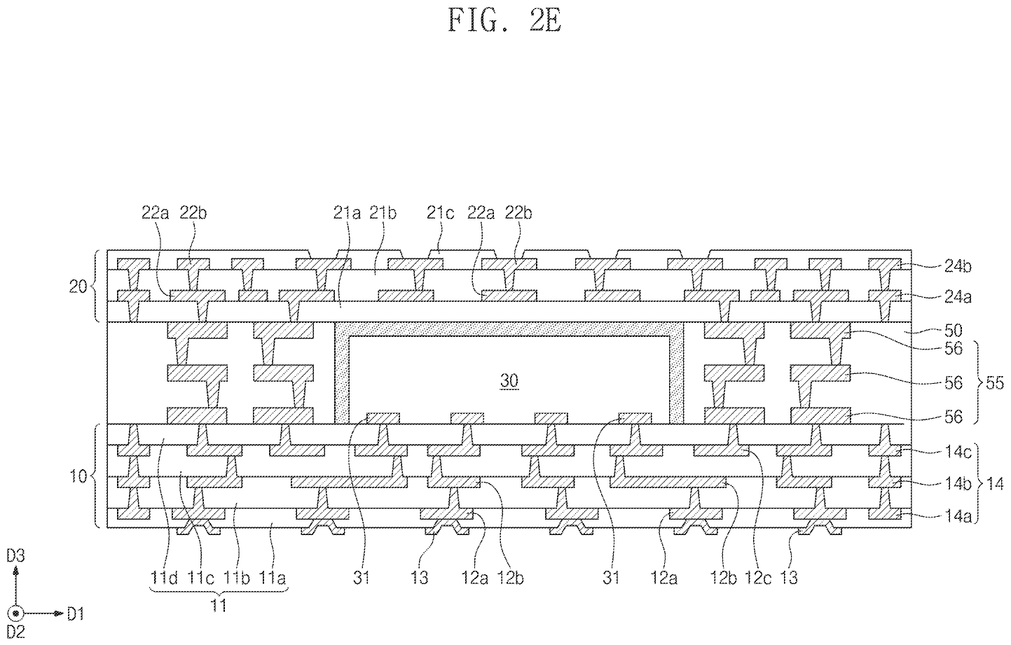

FIGS. 2A, 2B, 2C, 2D, and 2E illustrate cross-sectional views showing a method of fabricating a semiconductor package according to some implementations.

Referring to FIG. 2A, a first semiconductor chip 30, a connection dielectric layer 50, and connection conductive structures 55 may be formed on a support substrate 90. A first molding layer 60 may be formed to cover the first semiconductor chip 30.

Referring to FIG. 2B, the support substrate 90 may be removed. The first semiconductor chip 30, the connection dielectric layer 50, the connection conductive structure 55, and the first molding layer 60 may be turned upside down.

A fourth lower dielectric layer 11d may be formed on the first semiconductor chip 30 and the connection dielectric layer 50. Openings OP may be formed in the fourth lower dielectric layer 11d. The openings OP includes holes HO and a trench TE that surrounds the holes HO.

A conductive layer CL may be formed on the fourth lower dielectric layer 11d. The conductive layer CL may fill the openings OP. The conductive layer CL may include a conductive material. For example, the conductive layer CL may include copper.

Referring to FIG. 2C, the conductive layer CL may be patterned. The conductive layer CL may be patterned into third lower redistribution patterns 12c and third lower shield patterns 14c. The third lower redistribution patterns 12c may fill the holes HO of the openings OP. The third lower shield pattern 14c may fill the trench TE of the openings OP.

In some implementations, after the separation of the conductive layer CL into the third lower redistribution patterns 12c and the third lower shield patterns 14c, an etching process may be performed on the third lower shield patterns 14c. In this case, the third lower shield patterns 14c may have a height less than that of the third lower redistribution patterns 12c.

Referring to FIG. 2D, there may be formed first, second, and third lower dielectric layers 11a, 11b, and 11c, first and second lower redistribution patterns 12a and 12b, and first and second lower shield patterns 14a and 14b. The first, second, and third lower dielectric layers 11a, 11b, and 11c, the first and second lower redistribution patterns 12a and 12b, and the first and second lower shield patterns 14a and 14b may be formed by processes similar to those used for forming the fourth lower dielectric layer 11d, the third lower redistribution patterns 12c, and the third lower shield patterns 14c. Bump connection patterns 13 may be formed. Accordingly, a lower redistribution substrate 10 may be formed.

Referring to FIG. 2E, the lower redistribution substrate 10 may be turned upside down. First, second, and third upper dielectric layers 21a, 21b, and 21c, first and second upper redistribution patterns 22a and 22b, and first and second upper shield patterns 24a and 24b may be formed on the connection dielectric layer 50 and the first molding layer 60. The first, second, and third upper dielectric layers 21a, 21b, and 21c, the first and second upper redistribution patterns 22a and 22b, and the first and second upper shield patterns 24a and 24b may be formed by processes similar to those used for forming the fourth lower dielectric layer 11d, the third lower redistribution patterns 12c, and the third lower shield patterns 14c.

Referring to FIG. 1A, first and second bumps 81 and 82, a second semiconductor chip 40, and a second molding layer 70 may be formed.

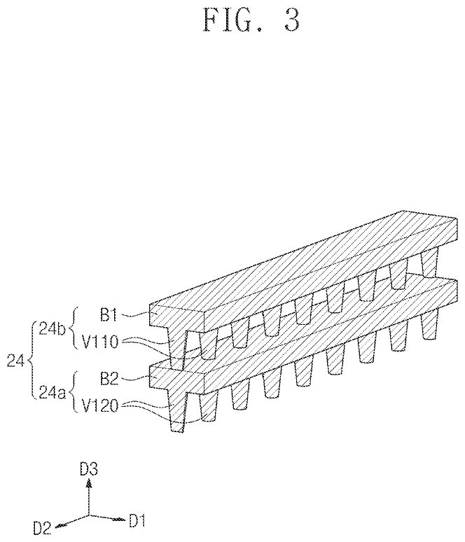

FIG. 3 illustrates a perspective view partially showing an upper shield structure of a semiconductor package according to some implementations. Except that discussed below, a semiconductor package of FIG. 3 may be similar to the semiconductor package of FIGS. 1A to 1G.

Referring to FIG. 3, the upper shield structure 24 of a semiconductor package includes a first upper shield pattern 24a and a second upper shield pattern 24b on the first upper shield pattern 24a.

The first upper shield pattern 24a includes a shield base part B2 and a plurality of shield via parts V120 connected to the shield base part B2. The shield via parts V120 of the first upper shield pattern 24a may be spaced apart from each other. The shield via parts V120 of the first upper shield pattern 24a may be arranged along an extending direction of the shield base part B2 of the first upper shield pattern 24a. For example, the shield base part B2 of the first upper shield pattern 24a may include one portion that extends in a second direction D2 and another portion that extends in a first direction D1. The shield via parts V120 connected to the one portion extending in the second direction D2 may be arranged in the second direction D2, and the shield via parts V120 connected to the another portion extending in the first direction D1 may be arranged in the first direction D1.

The second upper shield pattern 24b includes a shield base part B1 and a plurality of shield via parts V110 connected to the shield base part B1. The shield via parts V110 of the second upper shield pattern 24b may be spaced apart from each other. The shield via parts V110 of the second upper shield pattern 24b may be arranged along an extending direction of the shield base part B1 of the second upper shield pattern 24b.

In some implementations, similar to the upper shield patterns 24a and 24b, a lower shield pattern may include a plurality of shield via parts.

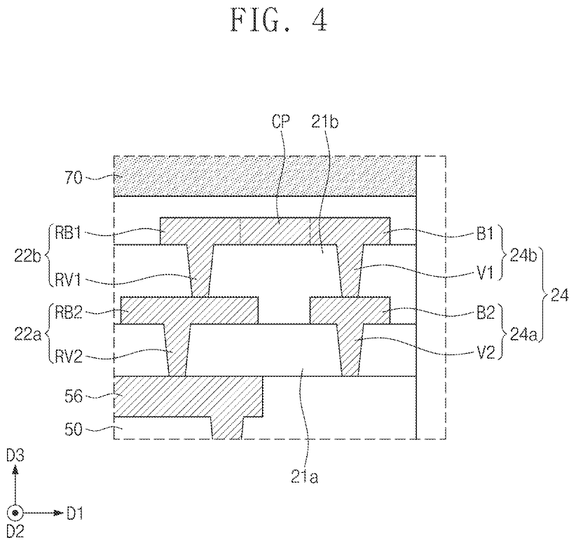

FIG. 4 illustrates an enlarged cross-sectional view showing a semiconductor package according to some implementations. Except that discussed below, a semiconductor package of FIG. 4 may be similar to the semiconductor package of FIGS. 1A to 1G.

Referring to FIG. 4, a semiconductor package includes a conductive pattern CP that connects the second upper shield pattern 24b to the second upper redistribution pattern 22b. It is discussed for convenience that the second upper shield pattern 24b, the second upper redistribution pattern 22b, and the conductive pattern CP are distinguished from each other, but the second upper shield pattern 24b, the second upper redistribution pattern 22b, and the conductive pattern CP may be connected into a single unitary structure with no boundary therebetween.

The conductive pattern CP may be connected to the shield base part B1 of the second upper shield pattern 24b and the redistribution base part RB1 of the second upper redistribution pattern 22b. The upper shield structure 24 may be electrically connected to a ground voltage through the conductive pattern CP, the first and second upper redistribution patterns 22a and 22b, the connection conductive patterns 56, and a lower redistribution substrate.

As the upper shield structure 24 is electrically connected to a ground voltage, the upper shield structure 24 may have an electromagnetic wave blocking effect.

In some implementations, a conductive pattern may be provided to connect the first upper shield pattern 24a to the first upper redistribution patterns 22a.

In some implementations, a conductive pattern may be provided to connect a lower shield structure to a lower redistribution pattern.

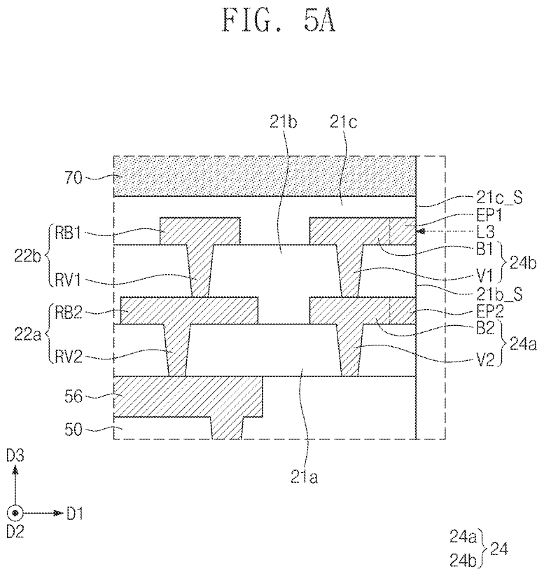

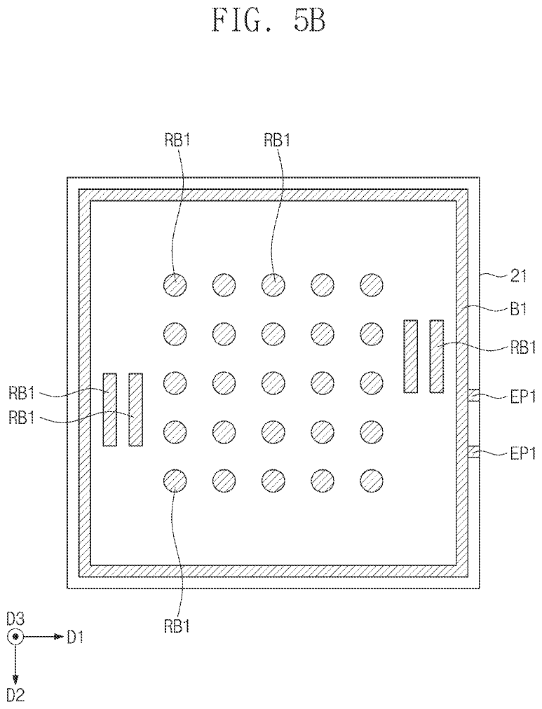

FIG. 5A illustrates an enlarged cross-sectional view showing a semiconductor package according to some implementations. FIG. 5B illustrates a plan view showing a planar structure at a level L3 of FIG. 5A. Except that discussed below, a semiconductor package of FIGS. 5A and 5B may be similar to the semiconductor package of FIGS. 1A to 1G.

Referring to FIGS. 5A and 5B, a semiconductor package includes a first exposure pattern EP1 and a second exposure pattern EP2. The first exposure pattern EP1 may be connected to the shield base part B1 of the second upper shield pattern 24b. It is discussed for convenience that the second upper shield pattern 24b and the first exposure pattern EP1 are distinguished from each other, but the second upper shield pattern 24b and the first exposure pattern EP1 may be connected into a single unitary structure with no boundary therebetween.

The second exposure pattern EP2 may be connected to the shield base part B2 of the first upper shield pattern 24a. It is discussed for convenience that the first upper shield pattern 24a and the second exposure pattern EP2 are distinguished from each other, but the first upper shield pattern 24a and the second exposure pattern EP2 may be connected into a single unitary structure with no boundary therebetween.

The first exposure pattern EP1 may be outwardly exposed through a sidewall 21c_S of the third upper dielectric layer 21c. The second exposure pattern EP2 may be outwardly exposed through a sidewall 21b_S of the second upper dielectric layer 21b.

In a semiconductor package according to some implementations, as the first and second exposure patterns EP1 and EP2 are included, electromagnetic waves may be discharged through the first and second exposure patterns EP1 and EP2, and the upper shield structure 24 may have an increased electromagnetic wave blocking effect.

In some implementations, a semiconductor package may include an exposure pattern connected to a lower shield structure.

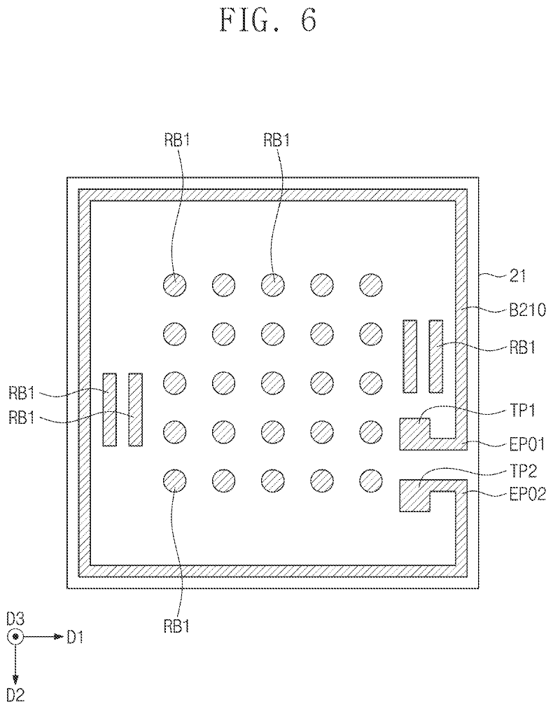

FIG. 6 illustrates a plan view showing a planar structure of an upper shield structure in a semiconductor package according to some implementations. Except that discussed below, a semiconductor package of FIG. 6 may be similar to the semiconductor package of FIGS. 1A to 1G.

Referring to FIG. 6, in a semiconductor package, a shield base part B210 of a second upper shield pattern includes a first end EPO1 and a second end EPO2 that face each other. The first end EPO1 and the second end EPO2 may be spaced apart from each other.

A first test pattern TP1 may be connected to the first end EPO1, and a second test pattern TP2 may be connected to the second end EPO2. The first and second test patterns TP1 and TP2 may have a width greater than that of the shield base part B210 of the second upper shield pattern. The width of the first and second test patterns TP1 and TP2 may be greater than that of the first and second ends EPO1 and EPO2 of the shield base part B210 included in the second upper shield pattern.

The first and second test patterns TP1 and TP2 may be formed simultaneously with the second upper shield pattern. After the formation of the first and second test patterns TP1 and TP2 and the second upper shield pattern, a test apparatus may be connected to the first and second test patterns TP1 and TP2 to test electrical properties of an upper shield structure, and it may be possible to determine the occurrence of crack in the upper shield structure.

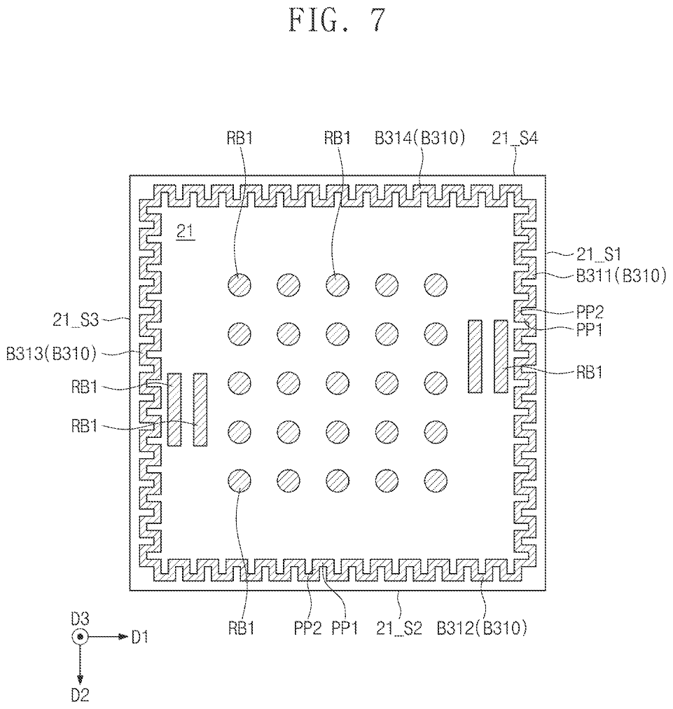

FIG. 7 illustrates a plan view showing a planar structure of an upper shield structure in a semiconductor package according to some implementations. Except that discussed below, a semiconductor package of FIG. 7 may be similar to the semiconductor package of FIGS. 1A to 1G.

Referring to FIG. 7, in a semiconductor package, a shield base part B310 of a second upper shield pattern includes a first portion B311 adjacent to a first sidewall 21_S1 of the upper dielectric structure 21, a second portion B312 adjacent to a second sidewall 21_S2 of the upper dielectric structure 21, a third portion B313 adjacent to a third sidewall 21_S3 of the upper dielectric structure 21, and a fourth portion B314 adjacent to a fourth sidewall 21_S4 of the upper dielectric structure 21.

Each of the first, second, third, and fourth portions B311, B312, B313, and B314 of the shield base part B310 included in the second upper shield pattern includes first patterns parts PP1 that extend in the first direction D1 and second pattern parts PP2 that extend in the second direction D2. The first pattern parts PP1 and the second pattern parts PP2 may be alternately connected to each other.

Similar to the shield base part B310 of the second upper shield pattern, a shield via part of the second upper shield pattern, a first upper shield pattern, and a lower shield structure may include pattern parts.

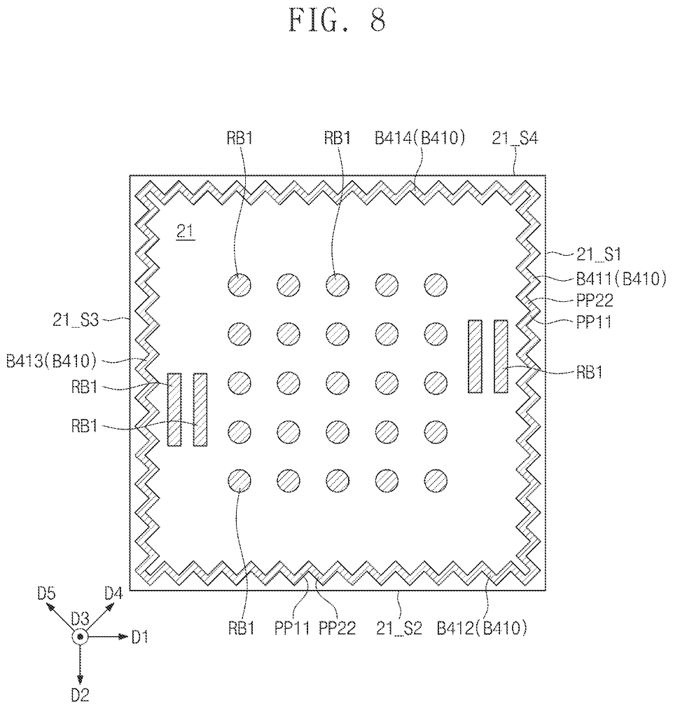

FIG. 8 illustrates a plan view showing a planar structure of an upper shield structure in a semiconductor package according to some implementations. Except that discussed below, a semiconductor package of FIG. 8 may be similar to the semiconductor package of FIG. 7.

Referring to FIG. 8, in a semiconductor package, a shield base part B410 of a second upper shield pattern includes a first portion B411 adjacent to a first sidewall 21_S1 of the upper dielectric structure 21, a second portion B412 adjacent to a second sidewall 21_S2 of the upper dielectric structure 21, a third portion B413 adjacent to a third sidewall 21_S3 of the upper dielectric structure 21, and a fourth portion B414 adjacent to a fourth sidewall 21_S4 of the upper dielectric structure 21.

Each of the first, second, third, and fourth portions B411, B412, B413, and B414 of the shield base part B410 included in the second upper shield pattern may have a zigzag shape.

Each of the first, second, third, and fourth portions B411, B412, B413, and B414 of the shield base part B410 included in the second upper shield pattern includes first pattern parts PP11 that extend in a fourth direction D4 and second pattern parts PP22 that extend in a fifth direction D5. The first pattern parts PP11 and the second pattern parts PP21 may be alternately connected to each other. The fourth direction D4 may intersect the first, second, and third directions D1, D2, and D3. For example, the fourth direction D4 may be a horizontal direction perpendicular to the third direction D3. The fifth direction D5 may intersect the first, second, third, and fourth directions D1, D2, D3, and D4. For example, the fifth direction D5 may be a horizontal direction perpendicular to the third direction D3.

Similar to the shield base part B410 of the second upper shield pattern, a shield via part of the second upper shield pattern, a first upper shield pattern, and a lower shield structure may have a zigzag shape.

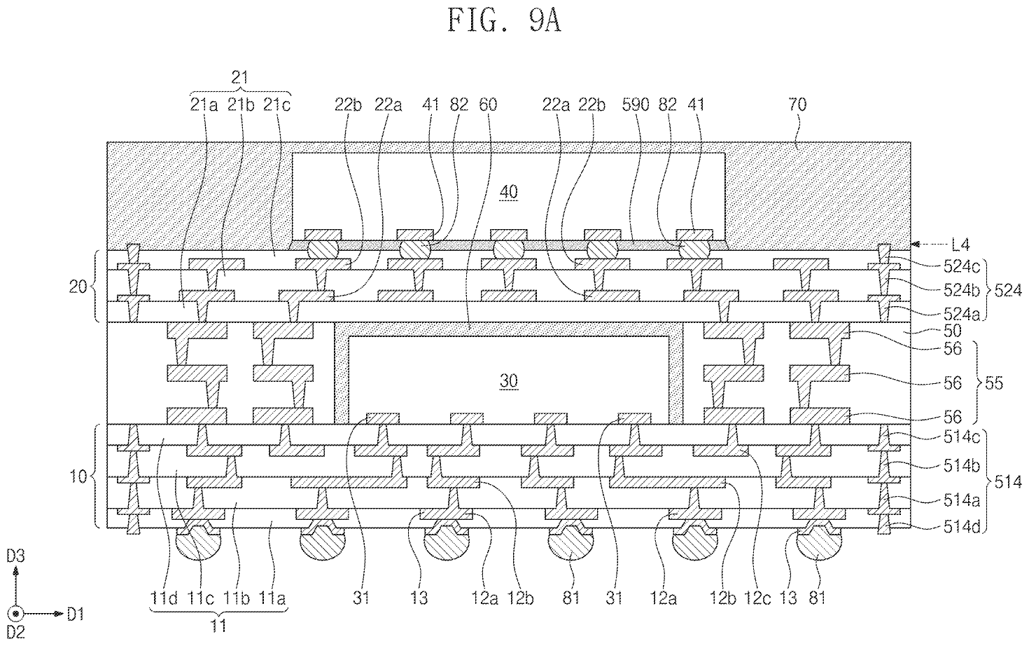

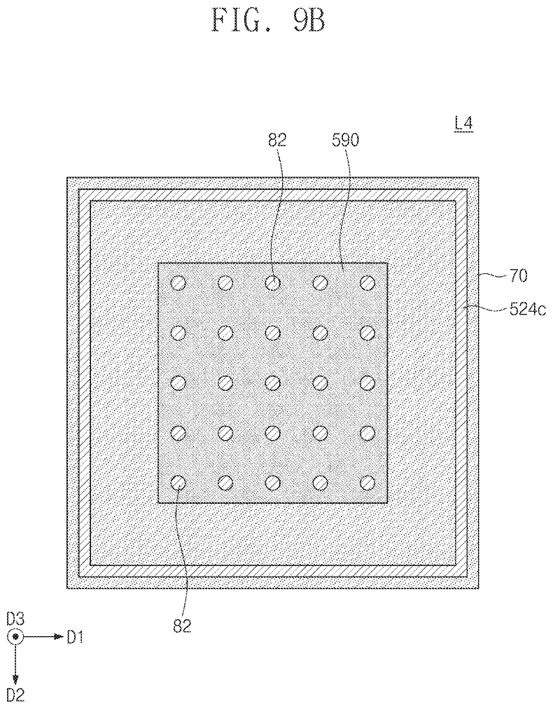

FIG. 9A illustrates a cross-sectional view showing a semiconductor package according to some implementations. FIG. 9B illustrates a planar view showing a planar structure at a level LA of FIG. 9A. Except that discussed below, a semiconductor package of FIGS. 9A and 9B may be similar to the semiconductor package of FIGS. 1A to 1G.

Referring to FIGS. 9A and 9B, an upper shield structure 524 includes a first upper shield pattern 524a, a second upper shield pattern 524b on the first upper shield pattern 524a, and an upper dam pattern 524c on the second upper shield pattern 524b.

The upper dam pattern 524c may include the same material as that of the first and second upper shield patterns 524a and 524b. For example the upper dam pattern 524c may include copper.

An underfill layer 590 may be provided between the second semiconductor chip 40 and the upper redistribution substrate 20. The underfill layer 590 may include a dielectric material.

When viewed in plan view as shown in FIG. 9B, the upper dam pattern 524c may have a tetragonal ring shape. The upper dam pattern 524c may surround the underfill layer 590 and the second bumps 82. The upper dam pattern 524c may serve as a dam that prevents a material of the underfill layer 590 from being outwardly discharged in a process for forming the underfill layer 590.

The upper dam pattern 524c may penetrate a top surface of the third upper dielectric layer 21c of the upper redistribution substrate 20. An upper portion of the upper dam pattern 524c may be covered with the second molding layer 70. An upper portion of the upper dam pattern 524c may be disposed in the second molding layer 70. A lower portion of the upper dam pattern 524c may be disposed in the third upper dielectric layer 21c of the upper dielectric structure 21.

A lower shield structure 514 includes a lower dam pattern 514d, a first lower shield pattern 514a on the lower dam pattern 514d, a second lower shield pattern 514b on the first lower shield pattern 514a, and a third lower shield pattern 514c on the second lower shield pattern 514b.

The lower dam pattern 514d may include the same material as that of the first, second, and third lower shield patterns 514a, 514b, and 514c. For example, the lower dam pattern 514d may include copper.

When viewed in plan, the lower dam pattern 514d may have a tetragonal ring shape. The lower dam pattern 514d may surround the bump connection patterns 13 and the first bumps 81. The lower dam pattern 514d may serve as a dam that prevents outward discharge of a material included in an underfill layer in a process for forming the underfill layer.

The lower dam pattern 514d may penetrate a bottom surface of the first lower dielectric layer 11a of the lower redistribution substrate 10. An upper portion of the lower dam pattern 514d may be disposed in the first lower dielectric layer 11a of the lower dielectric structure 11.

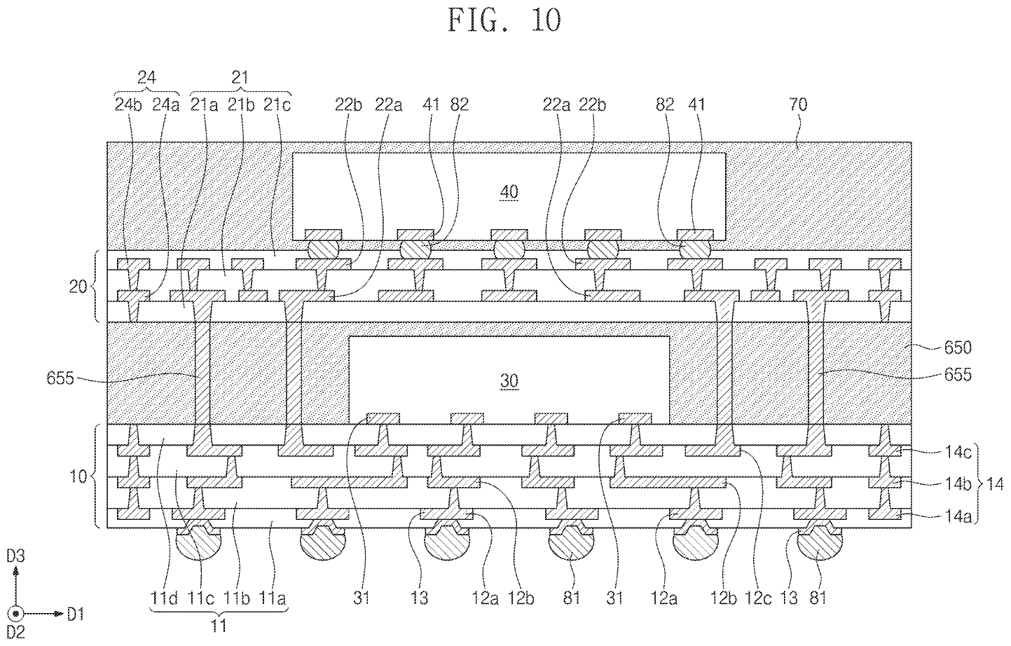

FIG. 10 illustrates a cross-sectional view showing a semiconductor package according to some implementations. Except that discussed below, a semiconductor package of FIG. 10 may be similar to the semiconductor package of FIGS. 1A to 1G.

Referring to FIG. 10, a connection dielectric layer 650 may be in contact with a top surface of the lower redistribution substrate 10 and a bottom surface of the upper redistribution substrate 20. The connection dielectric layer 650 may be in contact with a top surface and a sidewall of the first semiconductor chip 30. In some implementations, a width in the first direction D1 of the connection dielectric layer 650 may be the same as a width in the first direction D1 of the lower redistribution substrate 10 and a width in the first direction D1 of the upper redistribution substrate 20.

In some implementations, the connection dielectric layer 650 may include the same dielectric material as that of the second molding layer 70. For example, the connection dielectric layer 650 may include an epoxy resin.

A connection conductive structure 655 may have a pillar shape that extends in the third direction D3 and penetrates the connection dielectric layer 650. The connection conductive structure 655 may be in contact with the third lower redistribution pattern 12c and the first upper redistribution patterns 22a. The connection conductive structure 655 may include a conductive material. For example, the connection conductive structure 655 may include copper.

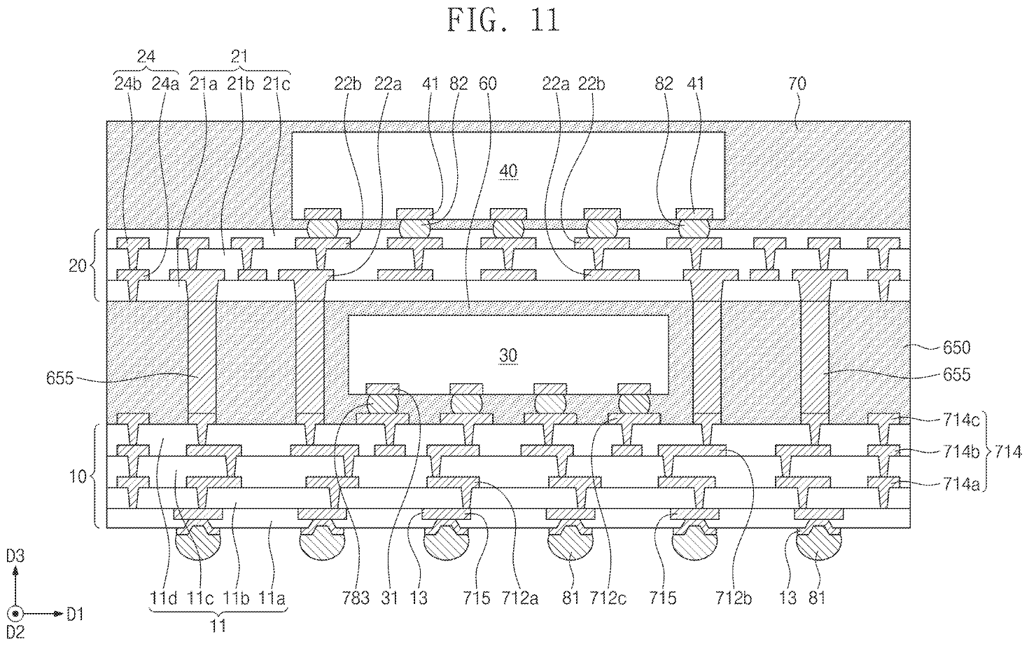

FIG. 11 illustrates a cross-sectional view showing a semiconductor package according to some implementations. Except that discussed below, a semiconductor package of FIG. 11 may be similar to the semiconductor package of FIGS. 1A to 1G.

Referring to FIG. 11, the lower redistribution substrate 10 includes a pad pattern 715 on the bump connection pattern 13. A first lower redistribution pattern 712a may be provided on the pad pattern 715. The pad pattern 715 may include a conductive material.

Each of first, second, and third lower redistribution patterns 712a, 712b, and 712c may include a redistribution via part and a redistribution base part on the redistribution via part. Each of first, second, and third lower shield patterns 714a, 714b, and 714c may include a shield via part and a shield base part on the shield via part.

A third bump 783 may be provided to connect the first pad 31 of the first semiconductor chip 30 to the third lower redistribution pattern 712c. The third bump 783 may include a conductive material.

After the formation of the lower redistribution substrate 10, the first semiconductor chip 30 may be mounted on the lower redistribution substrate 10.

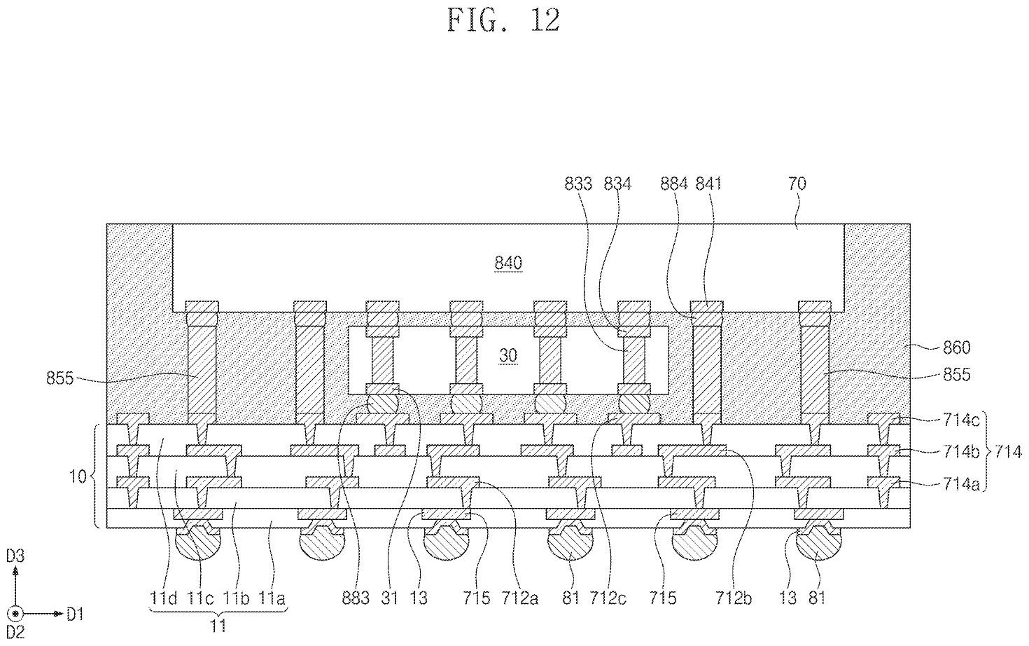

FIG. 12 illustrates a cross-sectional view showing a semiconductor package according to some implementations. Except that discussed below, a semiconductor package of FIG. 12 may be similar to the semiconductor package of FIGS. 1A to 1G or the semiconductor package of FIG. 11.

Referring to FIG. 12, the first semiconductor chip 30 includes a through via 833 on the first pad 31 and a second pad 834 on the through via 833. The through via 833 and the second pad 834 may include a conductive material.

A second semiconductor chip 840 may be mounted on the first semiconductor chip 30. The second semiconductor chip 840 includes third pads 841. The third pads 841 may include a conductive material. A width in the first direction D1 of the second semiconductor chip 840 may be less than a width in the first direction D1 of the lower redistribution substrate 10.

A second bump 883 may be provided to connect the first pad 31 to the third lower redistribution pattern 712c. Third bumps 884 may be provided which are connected to the third pads 841. The second and third bumps 883 and 884 may include a conductive material.

A connection via 855 may be provided to connect the third lower redistribution pattern 712c to the third bumps 884. The connection via 855 may include a conductive material. The second semiconductor chip 840 may be electrically connected to the lower redistribution substrate 10 through the third bumps 884 and the connection via 855.

A molding layer 860 may be provided to surround the first and second semiconductor chips 30 and 840. The molding layer 860 may include a dielectric material. The molding layer 860 may be in contact with a sidewall of the second semiconductor chip 840.

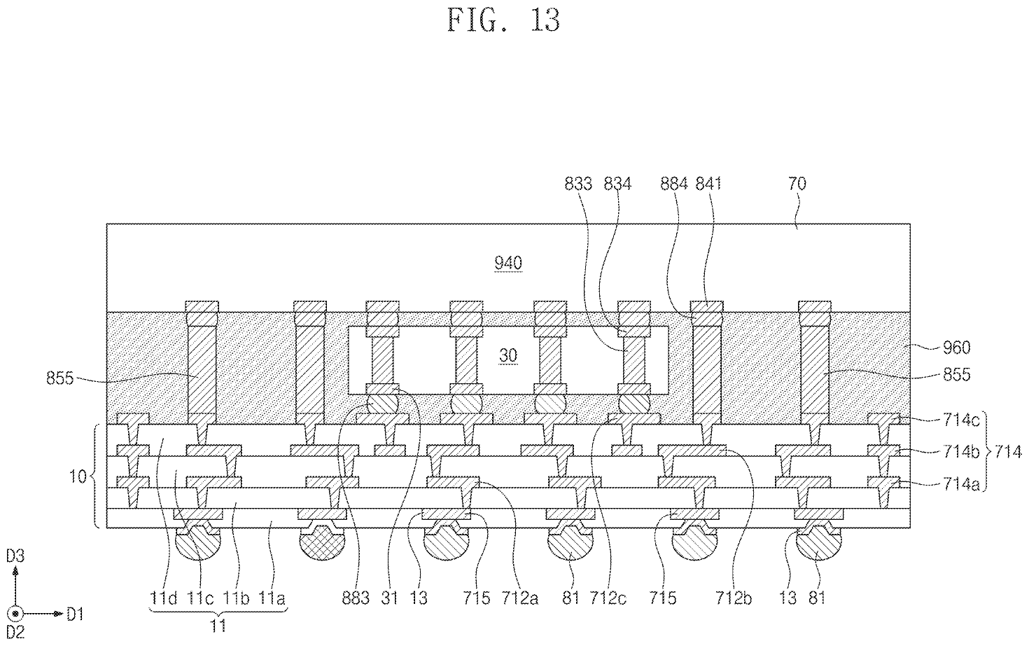

FIG. 13 illustrates a cross-sectional view showing a semiconductor package according to some implementations. Except that discussed below, a semiconductor package of FIG. 13 may be similar to the semiconductor package of FIG. 12.

Referring to FIG. 13, a width in the first direction D1 of a second semiconductor chip 940 may be the same as a width in the first direction D1 of the lower redistribution substrate 10. A molding layer 960 may be interposed between the second semiconductor chip 940 and the lower redistribution substrate 10. The lower redistribution substrate 10, the molding layer 960, and the second semiconductor chip 940 may have their sidewalls that are coplanar with each other.

In a semiconductor package according to some implementations, a shield structure may be included to improve stiffness of the semiconductor package and to protect the semiconductor package against external forces.

In a semiconductor package according to some implementations, a shield structure may be included to block electromagnetic waves.

In a semiconductor package according to some implementations, a size of a shield structure may be adjusted to minimize warpage of a redistribution substrate.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although the present invention has been described in connection with some implementations illustrated in the accompanying drawings, it will be understood by one of ordinary skill in the art that variations in form and detail may be made therein without departing from the spirit and essential feature of the present disclosure. The above disclosed implementations should thus be considered illustrative and not restrictive.

1. A semiconductor package, comprising:
a lower redistribution substrate;
an upper redistribution substrate; and
a semiconductor chip between the lower redistribution substrate and the upper redistribution substrate,
wherein the lower redistribution substrate includes:
a lower dielectric structure;
a lower redistribution pattern surrounded by the lower dielectric structure; and
a lower shield structure surrounded by the lower dielectric structure and surrounding the lower redistribution pattern, and
wherein the upper redistribution substrate includes:
an upper dielectric structure;
an upper redistribution pattern surrounded by the upper dielectric structure; and
an upper shield structure surrounded by the upper dielectric structure and surrounding the upper redistribution pattern.

2. The semiconductor package of claim 1, wherein
the upper shield structure includes a first upper shield pattern and a second upper shield pattern on the first upper shield pattern,
the first upper shield pattern includes a first shield via part and a first shield base part, the first shield base part having a width greater than a width of the first shield via part,
the second upper shield pattern includes a second shield via part and a second shield base part, the second shield base part having a width greater than a width of the second shield via part, and
the first shield via part and the second shield via part overlap each other.

3. The semiconductor package of claim 2, wherein the second shield via part includes:
a plurality of first portions that extend in a first direction; and
a plurality of second portions that extend in a second direction that intersects the first direction,
the upper redistribution pattern includes a redistribution via part and a redistribution base part, the redistribution base part having a width greater than a width of the redistribution via part,
the redistribution via part is between two first portions of the plurality of first portions of the second shield via part, and
the redistribution via part is between two second portions of the plurality of second portions of the second shield via part.

4. The semiconductor package of claim 2, wherein the width of the first shield via part decreases with decreasing distance from the lower redistribution substrate, and the width of the second shield via part decreases with decreasing distance from the lower redistribution substrate.

5. The semiconductor package of claim 2, wherein
the width of the first shield via part and the width of the second shield via part are in a range of about 10 μm to about 50 μm, and
the width of the first shield base part and the width of the second shield base part are in a range of 20 μm to about 100 μm.

6. The semiconductor package of claim 1, wherein the upper shield structure includes:
a plurality of first portions that extend in a first direction; and
a plurality of second portions that extend in a second direction that intersects the first direction,
wherein each first portion of the plurality of first portions of the upper shield structure has a length in the first direction of greater than a length of the semiconductor chip in the first direction.

7. The semiconductor package of claim 1,
wherein the upper redistribution substrate further includes a conductive pattern that electrically connects the upper shield structure to the upper redistribution pattern, and
wherein the upper shield structure is electrically connected to a ground voltage through the conductive pattern and the upper redistribution pattern.

8. The semiconductor package of claim 1, wherein the upper shield structure further includes an exposure pattern exposed on a sidewall of the upper dielectric structure.

9. The semiconductor package of claim 1,
wherein the upper shield structure further includes an upper dam pattern that penetrates a top surface of the upper dielectric structure, and
wherein the lower shield structure further includes a lower dam pattern that penetrates a bottom surface of the lower dielectric structure.

10. A semiconductor package, comprising:
a lower redistribution substrate; and
a semiconductor chip mounted on the lower redistribution substrate,
wherein the lower redistribution substrate includes:
a lower dielectric structure;
a first lower redistribution pattern surrounded by the lower dielectric structure;
a second lower redistribution pattern on the first lower redistribution pattern; and
a lower shield structure surrounded by the lower dielectric structure and surrounding the first lower redistribution pattern and the second lower redistribution pattern,
wherein the lower shield structure includes a first lower shield pattern and a second lower shield pattern on the first lower shield pattern,
wherein the first lower shield pattern is at a level the same as a level of the first lower redistribution pattern, and
wherein the second lower shield pattern is at a level the same as a level of the second lower redistribution pattern.

11. The semiconductor package of claim 10, wherein
the first lower shield pattern includes a first shield base part and a first shield via part, the first shield base part having a width less than a width of the first shield base part,
the first lower redistribution pattern includes a first redistribution base part and a first redistribution via part, the first redistribution via part having a width less than a width of the first redistribution base part,
a top surface of the first shield via part is at a level the same as a level of a top surface of the first redistribution via part, and
a bottom surface of the first shield base part is at a level the same as a level of a bottom surface of the first redistribution base part.

12. The semiconductor package of claim 11, wherein
the lower dielectric structure includes a first lower dielectric layer and a second lower dielectric layer on the first lower dielectric layer, and
a top surface of the first shield base part and a top surface of the first redistribution base part are in contact with a bottom surface of the second lower dielectric layer.

13. The semiconductor package of claim 12, wherein the second lower dielectric layer includes:
an inner part surrounded by the lower shield structure; and
an outer part that surrounds the lower shield structure.

14. The semiconductor package of claim 10, wherein the first lower shield pattern includes a first shield base part and a plurality of first shield via parts connected to the first shield base part,
wherein the plurality of first shield via parts are spaced apart from each other.

15. The semiconductor package of claim 14, wherein the plurality of first shield via parts are arranged along an extending direction of the first shield base part.

16. The semiconductor package of claim 10, further comprising:
a connection dielectric layer on the lower redistribution substrate;
a connection conductive structure in the connection dielectric layer; and
an upper redistribution substrate on the connection dielectric layer,
wherein a distance between the lower shield structure and the semiconductor chip is greater than a distance between the connection conductive structure and the semiconductor chip.

17. The semiconductor package of claim 16, wherein the upper redistribution substrate includes:
an upper dielectric structure;
an upper redistribution pattern surrounded by the upper dielectric structure; and
an upper shield structure surrounded by the upper dielectric structure and surrounding the upper redistribution pattern,
wherein the first lower shield patter, the second lower shield pattern, and the upper shield structure overlap each other.

18. The semiconductor package of claim 10, wherein a distance between an outer sidewall of the lower dielectric structure and the first lower shield pattern is less than a distance between the outer sidewall of the lower dielectric structure and the first lower redistribution pattern.

19. A semiconductor package, comprising:
a lower redistribution substrate;
a first semiconductor chip mounted on the lower redistribution substrate;
a connection dielectric layer that surrounds the first semiconductor chip;
a connection conductive structure in the connection dielectric layer;
an upper redistribution substrate on the connection dielectric layer; and
a second semiconductor chip mounted on the upper redistribution substrate,
wherein the lower redistribution substrate includes:
a lower dielectric structure;
a lower redistribution pattern surrounded by the lower dielectric structure; and
a lower shield structure surrounded by the lower dielectric structure and surrounding the lower redistribution pattern,
wherein a length of the lower shield structure is greater than a length of the first semiconductor chip.

20. The semiconductor package of claim 19, wherein the lower shield structure includes:
a first portion that extends in a first direction; and
a second portion that extends in a second direction that intersects the first direction,
wherein a length of the first portion of the lower shield structure in the first direction is greater than a length of the first semiconductor chip in the first direction.

21.-25. (canceled)
